(19) United States
(12) Patent Application Publication
(10) Pub. No.: US 2017/0062420 A1
(43) Pub. Date: Mar. 2, 2017

(54) SEMICONDUCTOR DEVICE

(71) Applicant: Samsung Electronics Co., Ltd., Suwon-si (KR)

(72) Inventors: Jung-Gun YOU, Ansan-si (KR); Dae-Lim KANG, Hwaseong-si (KR); Myung-Yoon UM, Seoul (KR); Jeong-Hyo LEE, Suwon-si (KR); Jae-Yup CHUNG, Yongin-si (KR); Jun-Sun HWANG, Suwon-si (KR); Bo-Cheol JEONG, Suwon-si (KR)

(73) Assignee: Samsung Electronics Co., Ltd., Suwon-si (KR)

(21) Appl. No.: 15/222,300

(22) Filed: Jul. 28, 2016

(30) Foreign Application Priority Data
Sep. 1, 2015 (KR) 10-2015-0123466

(51) Int. Cl. H01L 27/088; H01L 29/40; H01L 29/423

(52) U.S. Cl. CPC H01L 27/0886; H01L 29/4238; H01L 29/42376; H01L 29/408; H01L 29/0847

(57) ABSTRACT

A semiconductor device including a first fin pattern and a second fin pattern which have respective short sides facing each other and are separated from each other, a first field insulating layer which is around the first fin pattern and the second fin pattern, a second field insulating layer and a third field insulating layer which are between the first fin pattern and the second fin pattern, a first gate which is formed on the first fin pattern to intersect the first fin pattern, a second gate which is formed on the second field insulating layer, and a third gate which is formed on the third field insulating layer, wherein upper surfaces of the second and third field insulating layers protrude further upward than an upper surface of the first field insulating layer, and a distance between the first gate and the second gate is equal to a distance between the second gate and the third gate.

### CROSS-REFERENCE TO RELATED APPLICATION

This application claims priority from Korean Patent Application No. 10-2015-0123466 filed on Sep. 1, 2015 in the Korean Intellectual Property Office, and all the benefits accruing therefrom under 35 U.S.C. 119, the contents of which in its entirety are herein incorporated by reference.

### BACKGROUND

1. Field

Example embodiments of inventive concepts relate to a semiconductor device, and more particularly, to a semiconductor device including fin patterns.

2. Description of the Related Art

As one of the scaling techniques for increasing the density of a semiconductor device, a multi-gate transistor has been suggested. A multi-gate transistor is obtained by forming a fin- or nanowire-shaped multi-channel active pattern (or silicon body) on a substrate and forming a gate on the surface of the multi-channel active pattern.

The multi-gate transistor can be easily scaled because it uses a three-dimensional (3D) channel. In addition, the current control capability can be improved without the need to increase the gate length of the multi-gate transistor. Moreover, it is possible to effectively suppress a short channel effect (SCE) in which an electric potential of a channel region is affected by a drain voltage

### SUMMARY

Example embodiments of inventive concepts provide a semiconductor device having increased usable area of a chip and improved integration density and yield due to active patterns and field insulating layers formed such that an unnecessary dummy gate is not formed between cells.

However, example embodiments of inventive concepts are not restricted to the one set forth herein. The above and other aspects of example embodiments of inventive concepts will become more apparent to one of ordinary skill in the art to which the example embodiments of inventive concepts pertains by referencing the detailed description of example embodiments of inventive concepts given below.

According to an example embodiments of inventive concepts, there is provided a semiconductor device including a first fin pattern and a second fin pattern which have respective short sides facing each other and are separated from each other, a first field insulating layer around the first fin pattern and the second fin pattern, a second field insulating layer and a third field insulating layer which are between the first fin pattern and the second fin pattern, a first gate on the first fin pattern to intersect the first fin pattern, a second gate on the second field insulating layer, and a third gate on the third field insulating layer, wherein upper surfaces of the second and third field insulating layers protrude further upward than an upper surface of the first field insulating layer, and a distance between the first gate and the second gate is equal to a distance between the second gate and the third gate.

In some example embodiments of inventive concepts, further comprising a third fin pattern between the second field insulating layer and the third field insulating layer, wherein the third fin pattern lies on the same line as the first and second fin patterns.

In some example embodiments of inventive concepts, wherein a width of the second field insulating layer is equal to that of the third field insulating layer in a direction of long sides of the first fin pattern extend.

In some example embodiments of inventive concepts, wherein a height of the second field insulating layer from a lower surface of the first fin pattern is equal to a height of the third field insulating layer from the lower surface of the first fin pattern.

In some example embodiments of inventive concepts, wherein the second field insulating layer and the third field insulating layer are as a single layer, and no fin pattern is formed between the second field insulating layer and the third field insulating layer.

In some example embodiments of inventive concepts, wherein at least part of the second gate intersects the first fin pattern.

In some example embodiments of inventive concepts, wherein the second field insulating layer contacts a short side of the first fin pattern, and the third field insulating layer contacts a short side of the second fin pattern.

In some example embodiments of inventive concepts, wherein the second field insulating layer and the third field insulating layer have different heights.

In some example embodiments of inventive concepts, further comprising an elevated source/drain region in the first fin pattern between the first gate and the second gate, wherein the elevated source/drain region has an asymmetrical shape.

In some example embodiments of inventive concepts, further comprising a third gate on the second fin pattern to intersect the second fin pattern, wherein a distance between the second gate and the third gate is equal to a distance between the third gate and the fourth gate.

In some example embodiments of inventive concepts, wherein the upper surface of the second field insulating layer or the third field insulating layer is at a height equal to or higher than an upper surface of the first fin pattern.

In some example embodiments of inventive concepts, wherein the second field insulating layer further comprises a protrusion extends along the upper surface of the first fin pattern.

In some example embodiments of inventive concepts, wherein at least part of the second gate intersects the protrusion.

In some example embodiments of inventive concepts, wherein an upper surface of a portion of the first fin pattern overlapped by the first gate is at a different height from an upper surface of a portion of the first fin pattern overlapped by the protrusion.

In some example embodiments of inventive concepts, wherein a first height of the portion of the first fin pattern overlapped by the first gate is higher than a second height of the portion of the first fin pattern overlapped by the protrusion.

In some example embodiments of inventive concepts, further comprising gate spacers on both sidewalls of the second gate, wherein one of the gate spacers is not formed on the upper surface of the second field insulating layer.

In some example embodiments of inventive concepts, wherein the first through third gates are metal gates.

In some example embodiments of inventive concepts, further comprising a third fin pattern and a fourth fin pattern which have respective short sides facing each other and are separated from each other, wherein the first field insulating layer is around the third fin pattern and the fourth fin pattern, the second field insulating layer is between the third fin pattern and the fourth fin pattern, the second gate is on the second field insulating layer between the third fin pattern and the fourth fin pattern, and the third gate is on the fourth fin pattern.

In some example embodiments of inventive concepts, further including elevated source/drain regions on both sides of a region in which the third gate and the fourth fin pattern intersect each other, and a channel region in the fourth fin pattern under the third gate.

In some example embodiments of inventive concepts, wherein the second field insulating layer extends in a direction intersecting the first through fourth fin patterns.

In some example embodiments of inventive concepts, further comprising a fifth fin pattern and a sixth fin pattern which have respective short sides facing each other and are separated from each other, wherein the second field insulating layer or the third field insulating layer is between the fifth fin pattern and the sixth fin pattern.

According to another example embodiments of inventive concepts, there is provided a semiconductor device including first through third fin patterns which have respective short sides facing each other and are separated from each other, a first field insulating layer around the first through third fin patterns, a second field insulating layer between the first fin pattern and the second fin pattern, a third field insulating layer between the second fin pattern and the third fin pattern, a first gate on the first fin pattern to intersect the first fin pattern, a second gate on the second field insulating layer, and a third gate on the third field insulating layer, wherein upper surfaces of the second and third field insulating layers protrude further upward than an upper surface of the first field insulating layer.

In some example embodiments of inventive concepts, wherein a distance between the first gate and the second gate is equal to a distance between the second gate and the third gate.

In some example embodiments of inventive concepts, wherein a width of the second field insulating layer is equal to that of the third field insulating layer in a direction in which long sides of the first fin pattern extend.

In some example embodiments of inventive concepts, wherein a height of the second field insulating layer from a lower surface of the first fin pattern is equal to a height of the third field insulating layer from the lower surface of the first fin pattern.

In some example embodiments of inventive concepts, further comprising a fourth fin pattern and a fifth fin pattern which have respective short sides facing each other and are separated from each other, wherein the first field insulating layer is around the fourth fin pattern and the fifth fin pattern, the second field insulating layer is between the fourth fin pattern and the fifth fin pattern, the second gate is on the second field insulating layer between the fourth fin pattern and the fifth fin pattern, and the third gate is on the fifth fin pattern.

In some example embodiments of inventive concepts, wherein a region between the first fin pattern and the second fin pattern lies on the same line as a region between the forth fin pattern and the fifth fin pattern.

In some example embodiments of inventive concepts, wherein a height of the second field insulating layer between the first fin pattern and the second fin pattern is equal to a height of the second field insulating layer between the fourth fin pattern and the fifth fin pattern.

In some example embodiments of inventive concepts, further comprising an elevated source/drain region in the first fin pattern between the first gate and the second gate, wherein the elevated source/drain region has an asymmetrical shape.

In some example embodiments of inventive concepts, wherein the second field insulating layer further comprises a protrusion along an upper surface of the first fin pattern.

In some example embodiments of inventive concepts, wherein at least part of the second gate intersects the protrusion.

In some example embodiments of inventive concepts, further comprising a sixth fin pattern and a seventh fin pattern which have respective short sides facing each other and are separated from each other, wherein the second field insulating layer or the third field insulating layer is between the sixth fin pattern and the seventh fin pattern.

In some example embodiments of inventive concepts, further comprising a fourth fin pattern and a fifth fin pattern which have respective short sides facing each other and are separated from each other, wherein the first field insulating layer is around the fourth fin pattern and the fifth fin pattern, the second and third field insulating layers are between the fourth fin pattern and the fifth fin pattern, the second gate is on the second field insulating layer, and the third gate is on the third field insulating layer.

In some example embodiments of inventive concepts, wherein the second fin pattern contains the same material as the first fin pattern and the third fin pattern.

In some example embodiments of inventive concepts, wherein the second fin pattern contains impurities of source/drain regions of the first gate.

According to another example embodiments of inventive concepts, there is provided a semiconductor device including a first fin pattern and a second fin pattern which have respective short sides facing each other and are separated from each other, a first field insulating layer around the first fin pattern and the second fin pattern, a second field insulating layer between the first fin pattern and the second fin pattern, a first gate on the first fin pattern to intersect the first fin pattern, a second gate on the second field insulating layer on one side, and a third gate on the second field insulating layer on the other side, and a fourth gate on the second fin pattern to intersect the second fin pattern,

wherein an upper surface of the second field insulating layer protrudes further upward than an upper surface of the first field insulating layer, and the first through fourth gates are sequentially arranged at regular intervals.

In some example embodiments of inventive concepts, wherein the second field insulating layer contacts facing short sides of the first and second fin patterns.

In some example embodiments of inventive concepts, wherein the upper surface of the second field insulating layer is at a height equal to or higher than upper surfaces of the first and second fin patterns.

In some example embodiments of inventive concepts, wherein the second field insulating layer comprises a first portion and a second portion which are located sequentially from a short side of the first fin pattern, wherein a height of the first portion is different from that of the second portion.

In some example embodiments of inventive concepts, wherein a height from a lower surface of the first fin pattern to an upper surface of the first portion is greater than a height from the lower surface of the first fin pattern to an upper surface of the second portion.

In some example embodiments of inventive concepts, the second gate and the third gate have different shapes.

In some example embodiments of inventive concepts, wherein the second field insulating layer comprises first through third portions sequentially from a short side of the first fin pattern, wherein a height of the first portion is different from that of the second portion, and a height of the third portion is equal to that of the first portion.

In some example embodiments of inventive concepts, wherein the height of the second portion is equal to that of the first field insulating layer.

In some example embodiments of inventive concepts, wherein the second field insulating layer further comprises a protrusion along the upper surface of the first fin pattern.

In some example embodiments of inventive concepts, wherein an upper surface of a portion of the first fin pattern overlapped by the first gate is at a different height from an upper surface of a portion of the first fin pattern overlapped by the protrusion.

In some example embodiments of inventive concepts, further comprising a third fin pattern and a fourth fin pattern which have respective short sides facing each other and are separated from each other, wherein the first field insulating layer is around the third fin pattern and the fourth fin pattern, the second field insulating layer is between the third fin pattern and the fourth fin pattern, the second gate is on the second field insulating layer between the third fin pattern and the fourth fin pattern, and the third gate is on the fourth fin pattern.

According to another example embodiments of inventive concepts, there is provided a semiconductor device including a first fin pattern and a second fin pattern which have respective short sides facing each other and are separated from each other, a third fin pattern and a fourth fin pattern which have respective short sides facing each other and are separated from each other, a first field insulating layer around the first through fourth fin patterns, a second field insulating layer between the first fin pattern and the second fin pattern, a third field insulating layer between the third fin pattern and the fourth fin pattern, a first gate which intersects the first fin pattern and the third fin pattern, a second gate on the second field insulating layer and the third field insulating layer, and a third gate only on the second field insulating layer, wherein upper surfaces of the second and third field insulating layers protrude further upward than an upper surface of the first field insulating layer.

In some example embodiments of inventive concepts, wherein a distance between the first gate and the second gate is equal to a distance between the second gate and the third gate.

In some example embodiments of inventive concepts, wherein the second field insulating layer and the third field insulating layer have different widths in a direction in which long sides of the first fin pattern extend.

In some example embodiments of inventive concepts, wherein part of the third gate is on the fourth fin pattern.

In some example embodiments of inventive concepts, wherein at least part of the second gate is on the first fin pattern.

In some example embodiments of inventive concepts, wherein the second field insulating layer comprises a first portion and a second portion sequentially from a short side of the first fin pattern and further comprising a fifth fin pattern located between the first portion and the second portion, wherein the fifth fin pattern lies on the same line as the first and second fin patterns.

In some example embodiments of inventive concepts, wherein a height from a lower surface of the first fin pattern to an upper surface of the first portion is equal to a height from the lower surface of the first fin pattern to an upper surface of the second portion.

In some example embodiments of inventive concepts, the first portion and the second portion have equal widths in the direction in which the long sides of the first fin extend.

In some example embodiments of inventive concepts, a semiconductor device comprising a first fin pattern on a substrate, a part of the first fin pattern surrounded by a first field insulating layer, a second fin pattern on the substrate, separated from the first fin pattern; the first field insulating layer on the substrate extending in a first direction along a long side of the first fin pattern, a second field insulating layer on the substrate extending in a second direction perpendicular to the first direction, a first gate on the first fin pattern; and a second gate on the second field insulating layer.

In some example embodiments of inventive concepts, the semiconductor device further comprises an elevated source/drain region, wherein the elevated source/drain region has an asymmetrical shape.

In some example embodiments of inventive concepts, wherein the second field insulating layer includes a protrusion along an upper surface of the first fin pattern.

In some example embodiments of inventive concepts, wherein an upper surface of a portion of the first fin pattern overlapped by the first gate is at a different height from an upper surface of a portion of the first fin pattern overlapped by the protrusion. In some example embodiments of inventive concepts, wherein the second fin pattern is of the same material as the first fin pattern.

### BRIEF DESCRIPTION OF THE DRAWINGS

The above and other aspects and features of example embodiments of inventive concepts will become more apparent by describing in detail example embodiments thereof with reference to the attached drawings, in which:

FIGS. 1A-2 respectively are plan and perspective views of a semiconductor device according to an example embodiments of inventive concepts;

FIG. 3 is a partial perspective view of fin patterns and field insulating layers of the semiconductor device of FIGS. 1A-2;

FIGS. 4A and 4B are cross-sectional views taken along the line A-A of FIGS. 1A-2;

FIG. 5 is a cross-sectional view taken along the line B-B of FIGS. 1A-2;

FIG. 6 illustrates a modified example of the semiconductor device of FIGS. 1A through 5;

FIG. 7 illustrates another modified example of the semiconductor device of FIGS. 1A through 5;

FIG. 8A illustrates another modified example of the semiconductor device of FIGS. 1A through 5;

FIG. 8B illustrates another modified example of the semiconductor device of FIGS. 1A through 5;

FIGS. 9A and 9B are a plan view of a semiconductor device according to another example embodiment of inventive concepts;

FIG. 10 is a cross-sectional view taken along the line C-C of FIG. 9A;

FIG. 11 is a cross-sectional view taken along the line D-D of FIG. 9A;

FIG. 12 illustrates a modified example of the semiconductor device of FIGS. 9A through 11;

FIG. 13 illustrates another modified example of the semiconductor device of FIGS. 9A through 11;

FIG. 14A illustrates another modified example of the semiconductor device of FIGS. 9A through 11;

FIG. 14B illustrates another modified example of the semiconductor device of FIGS. 9A through 11;

FIG. 15 illustrates a semiconductor device according to another example embodiments of inventive concepts;

FIG. 16 illustrates a semiconductor device according to another embodiment of inventive concepts;

FIG. 17 illustrates a semiconductor device according to another embodiment of inventive concepts;

FIGS. 18 and 19 respectively are plan and perspective views of a semiconductor device according to another embodiment of inventive concepts;

FIG. 20 is a partial perspective view of fin patterns and field insulating layers of the semiconductor device of FIGS. 18 and 19;

FIG. 21 is a cross-sectional view taken along the line F-F of FIGS. 18 and 19;

FIG. 22 illustrates a modified example of the semiconductor device of FIGS. 18 through 21;

FIG. 23 illustrate another modified example of the semiconductor device of FIGS. 18 through 21;

FIG. 24 illustrates another modified example of the semiconductor device of FIGS. 18 through 21;

FIG. 25 illustrates another modified example of the semiconductor device of FIGS. 18 through 21;

FIG. 26A illustrates another modified example of the semiconductor device of FIGS. 18 through 21;

FIG. 26B illustrates another modified example of the semiconductor device of FIGS. 18 through 21;

FIG. 27 illustrates a semiconductor device according to another example embodiments of inventive concepts;

FIGS. 28A and 28B illustrate a semiconductor device according to another example embodiment of inventive concepts;

FIG. 29 illustrates a semiconductor device according to another example embodiment of inventive concepts;

FIG. 30 illustrates a semiconductor device according to another example embodiment of inventive concepts; and

FIG. 31 is a block diagram of a system-on-chip (SoC) system including semiconductor devices according to example embodiments of inventive concepts.

### DETAILED DESCRIPTION

Advantages and features of example embodiments of inventive concepts and methods of accomplishing the same may be understood more readily by reference to the following detailed description of preferred example embodiments and the accompanying drawings. The example embodiments of inventive concepts may, however, be embodied in many different forms and should not be construed as being limited to the example embodiments set forth herein. Rather, these example embodiments are provided so that this disclosure will be thorough and complete and will fully convey the concept of the inventive concepts to those skilled in the art, and example embodiments of inventive concepts will only be defined by the appended claims. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the inventive concepts (especially in the context of the following claims) are to be construed to cover both the singular and the plural, unless otherwise indicated herein or clearly contradicted by context. The terms “comprising,” “having,” “including,” and “containing” are to be construed as open-ended terms (e.g., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of example embodiments of inventive concepts.

The example embodiments of inventive concepts will be described with reference to perspective views, cross-sectional views, and/or plan views, in which preferred example embodiments of the inventive concepts are shown. Thus, the profile of an example view may be modified according to manufacturing techniques and/or allowances. That is, the example embodiments of the inventive concepts are not intended to limit the scope of example embodiments of t inventive concepts but cover all changes and modifications that can be caused due to a change in manufacturing process. Thus, regions shown in the drawings are illustrated in schematic form and the shapes of the regions are presented simply by way of illustration and not as a limitation.

Unless defined otherwise, all technical and scientific terms used herein have the same meaning as commonly understood by one of ordinary skill in the art to which this inventive concept belongs. It is noted that the use of any and all examples, or example terms provided herein is intended merely to better illuminate the inventive concept and is not a limitation on the scope of the inventive concept unless otherwise specified. Further, unless defined otherwise, all terms defined in generally used dictionaries may not be overly interpreted.

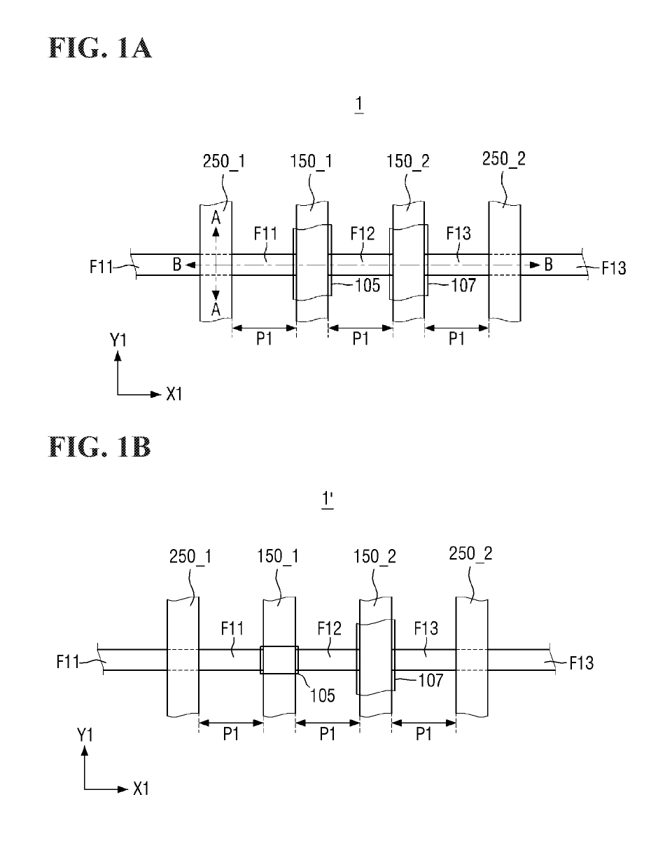

Hereinafter, semiconductor devices according to example embodiments of inventive concepts will be described with reference to FIGS. 1A through 31.

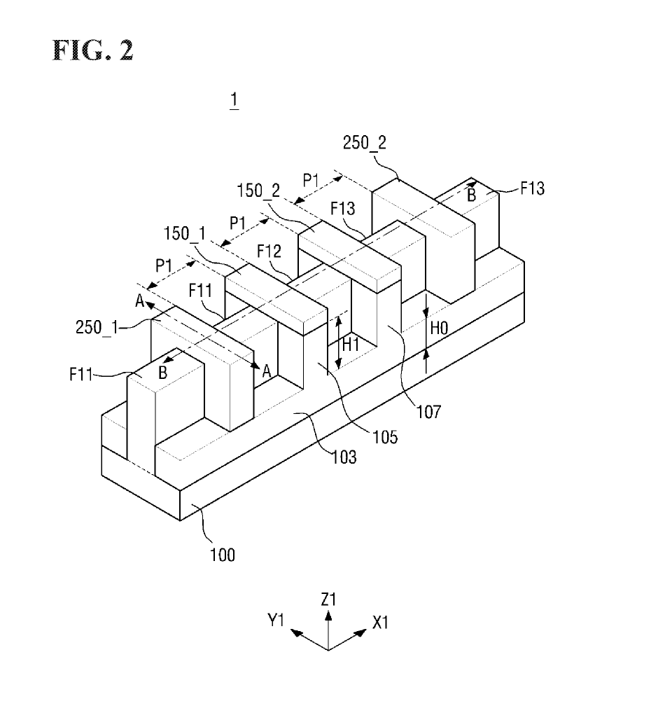

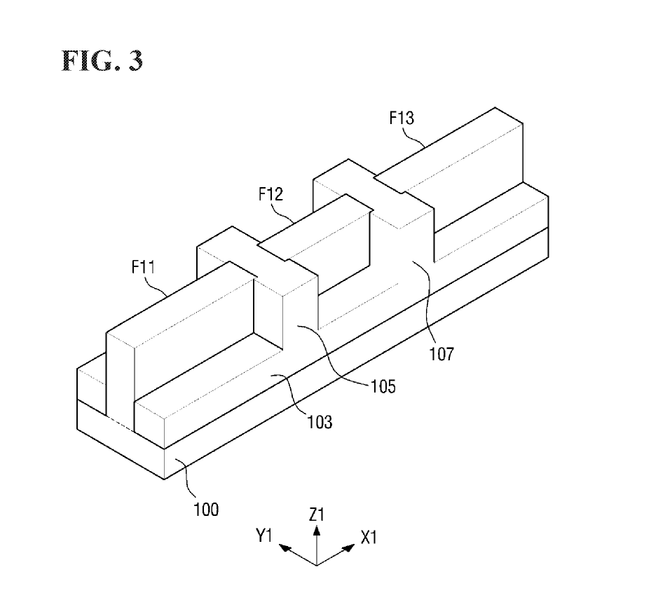

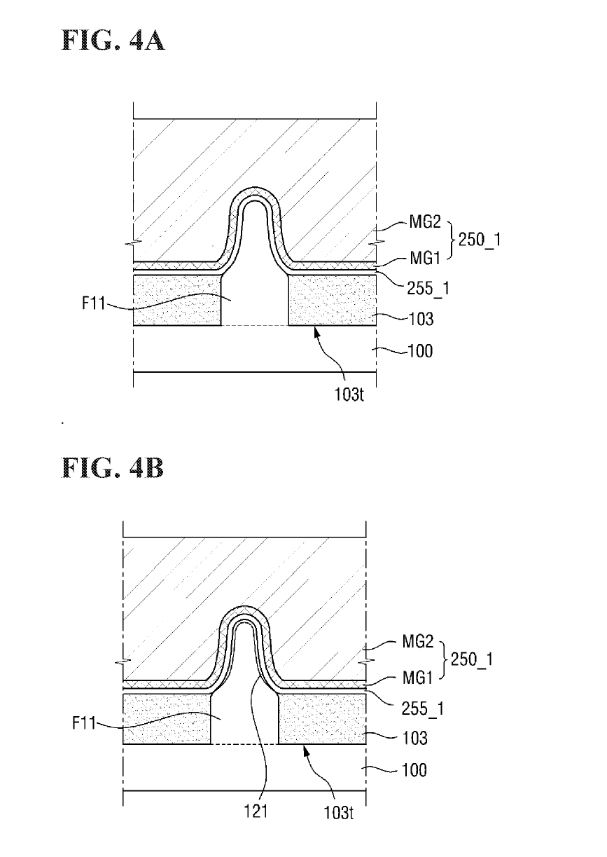

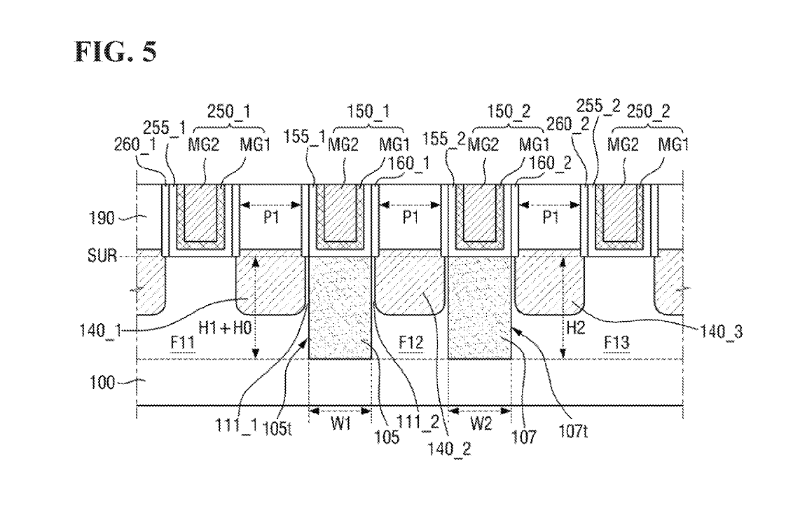

FIGS. 1A-2 are plan and perspective views respectively of a semiconductor device 1 according to an example embodiment of inventive concepts. FIG. 3 is a partial perspective view of fin patterns and field insulating layers of the semiconductor device 1 of FIGS. 1A-2. FIGS. 4A and 4B are cross-sectional views taken along the line A-A of FIGS. 1A-2. FIG. 5 is a cross-sectional view taken along the line B-B of FIGS. 1A-2.

For reference, the fin patterns illustrated in FIGS. 1A through 3 include source/drain regions formed thereon.

In addition, while bodies shaped like fin patterns are illustrated in the drawings, bodies shaped like wire patterns instead of the fin patterns can also be formed.

Referring to FIGS. 1A-1B, the semiconductor devices 1 and 1′, according to some example embodiments, may include second and third field insulating layers 105 and 107, first through third fin patterns F11 through F13, and first through fourth gates 250_1, 150_1, 150_2 and 250_2. The second field insulating layer 105 of FIG. 1A may extend longer in a second direction Y1 than the second field insulating layer 105 of FIG. 1B. The half left side (or alternatively half right side) of FIGS. 1A and 1B, including the first fin pattern F11, the second fin pattern F12, the first gate 250_1, the second gate 150_1 and the second field insulating layer 105, may illustrate a half cell of semiconductor devices 1 and 1′. In FIG. 1B, the size of the second field insulating layer 105 (and/or the third field insulating layer 107) may be reduced as compared to FIG. 1A.

Referring to FIGS. 1A through 5, the semiconductor device 1 according to the current example embodiment may include the first through the third field insulating layers 103, 105 and 107, the first through the third fin patterns F11 through F13, and the first through the fourth gates 250_1, 150_1, 150_2 and 250_2.

A substrate 100 may be, for example, a silicon substrate, a bulk silicon substrate, or a silicon-on-insulator (SOI) substrate. Otherwise, the substrate 100 may contain an element semiconductor such as germanium or a compound semiconductor such as a group Iv-Iv compound semiconductor or a group III-v compound semiconductor. Alternatively, the substrate 100 may consist of a base substrate and an epitaxial layer formed on the base substrate.

The first through third fin patterns F11 through F13 may protrude from the substrate 100. The first through third fin patterns F11 through F13 may extend along a first direction X1. The first through third fin patterns F11 through F13 may be formed side by side with each other in a lengthwise direction. That is, the first through third fin patterns F11 through F13 may lie on the same line. In addition, the first through third fin patterns F11 through F13 may be separated from each other.

Since the first fin pattern F11 extends along the first direction X1, it may include long sides extending along the first direction X1 and short sides extending along a second direction Y1.

When the first fin pattern F11 and the second fin pattern F12 are side by side along the lengthwise direction, it means that a short side of the first fin pattern F11 faces a short side of the second fin pattern F12. When the second fin pattern F12 and the third fin pattern F13 are side by side in the lengthwise direction, it means that a short side of the second fin pattern F12 faces a short side of the third fin pattern F13.

In the drawings, the first through third fin patterns F11 through F13 are shaped like rectangular parallelepipeds. However, the shape of the first through third fin patterns F11 through F13 is not limited to the rectangular parallelepipeds. That is, the first through third fin patterns F11 through F13 can have a chamfered shape, e.g., have rounded corners.

Even if the corners of the first through third fin patterns F11 through F13 are rounded, it is obvious that long and short sides of the first through third fin patterns F11 through F13 can be distinguished by those of ordinary skill in the art.

The first through third fin patterns F11 through F13 are active patterns used in a multi-gate transistor. That is, a channel may be formed along three surfaces of each of the first through third fin patterns F11 through F13 or may be formed on two facing surfaces of each of the first through third fin patterns F11 through F13.

Each of the first through third fin patterns F11 through F13 may be part of the substrate 100 or may include an epitaxial layer grown from the substrate 100.

The first through third fin patterns F11 through F13 may contain an element semiconductor material such as silicon or germanium. In addition, the first through third fin patterns F11 through F13 may contain a compound semiconductor such as a group IV-IV compound semiconductor or a group III-V compound semiconductor.

Specifically, the group IV-IV compound semiconductor may be, for example, a binary or ternary compound containing two or more of carbon (C), silicon (Si), germanium (Ge) and tin (Sn) or a compound obtained by doping the binary or ternary compound with a group IV element.

The group III-V compound semiconductor may be, for example, a binary, ternary, or quaternary compound composed of at least one of aluminum (Al), gallium (Ga) and indium (In) (e.g., group III elements) bonded with one of phosphorus (P), arsenic (As) and antimony (Sb) (e.g., group V elements).

The first through third fin patterns F11 through F13 may contain the same material. In addition, source/drain regions formed in the first through third fin patterns F11 through F13 may contain the same impurities. Also, respective upper surfaces SUR of the first through third fin patterns F11 through F13 may be located in the same plane. However, example embodiments of inventive concepts are not limited thereto.

In the semiconductor device 1 according to the current example embodiment, the first through third fin patterns F11 through F13 are described as silicon fin patterns that contain silicon.

As illustrated in FIGS. 3 through 5, a first trench 103t may be formed around the first through third fin patterns F11 through F13. The first trench 103t may expose the long sides of the first fin pattern F11.

A second trench 105t may be formed between the first fin pattern F11 and the second fin pattern F12. The second trench 105t may expose a short side of the first fin pattern F11 and a short side of the second fin pattern F12.

A third trench 107t may be formed between the second fin pattern F12 and the third fin pattern F13. The third trench 107t may expose a short side of the second fin pattern F12 and a short side of the third fin pattern F13.

That is, the second trench 105t may be disposed between the facing short sides of the first fin pattern F11 and the second fin pattern F12. The third trench 107t may be disposed between the facing short sides of the second fin pattern F12 and the third fin pattern F13.

In the semiconductor device 1 according to the current example embodiment, a depth of the second trench 105t may be equal to that of the third trench 107t. This is because the second trench 105t and the third trench 107t can be formed simultaneously. However, when the second trench 105t and the third trench 107t are formed separately, the depth of the second trench 105t may be different from that of the third trench 107t.

Further, in the semiconductor device 1 according to the current example embodiment, a width W1 of the second trench 105t in the first direction X1 may be equal to a width W2 of the third trench 107t in the first direction X1.

The first through third field insulating layers 103, 105 and 107 may be formed on the substrate 100 and disposed around the first through third fin patterns F11 through F13. The first through third field insulating layers 103, 105 and 107 may be formed to partially cover the first through third fin patterns F11 through F13.

The first field insulating layer 103 may extend along the first direction X1, and the second field insulating layer 105 and the third field insulating layer 107 may extend along the second direction Y1.

Each of the first through third field insulating layers 103, 105 and 107 may be, for example, an oxide layer, a nitride layer, an oxynitride layer, or a combination of these layers.

The first field insulating layer 103 may contact the long sides of the first fin pattern F11. The second field insulating layer 105 may contact a short side of the first fin pattern F11 and a short side of the second fin pattern F12. The third field insulating layer 107 may contact a short side of the second fin pattern F12 and a short side of the third fin pattern F13.

In other words, the first field insulating layer 103 may be located around the first fin pattern F11 and the second fin pattern F12, the second field insulating layer 105 may be located between the first fin pattern F11 and the second fin pattern F12, and the third field insulating layer 107 may be located between the second fin pattern F12 and the third fin pattern F13.

In addition, the second field insulating layer 105 may cover an end of the first fin pattern F11 and an end of the second fin pattern F12. Likewise, the third field insulating layer 107 may cover an end of the second fin pattern F12 and an end of the third fin pattern F13.

Here, an upper surface of the second field insulating layer 105 and an upper surface of the third field insulating layer 107 may protrude further upward than an upper surface of the first field insulating layer 103. Therefore, the first field insulating layer 103 may be formed in at least part of the first trench 103t. The second field insulating layer 105 may completely fill the second trench 105t, and the third field insulating layer 107 may completely fill the third trench 107t.

For example, the first field insulating layer 103 may have a height of HO, and the second field insulating layer 105 or the third field insulating layer 107 may have a height of H0+H1. That is, the second field insulating layer 105 and the third field insulating layer 107 may be higher than the first field insulating layer 103 by H1.

In addition, the upper surface of the second field insulating layer 105 may lie in the same plane with the upper surface SUR of the first fin pattern F11. Likewise, the upper surface of the third field insulating layer 107 may lie in the same plane with the upper surface SUR of the first fin pattern F11. That is, the upper surface of the second field insulating layer 105 may lie in the same plane with the upper surface of the third field insulating layer 107, but example embodiments of inventive concepts are not limited thereto.

The second field insulating layer 105 and the third field insulating layer 107 may be separated from each other. A width W1 of the second field insulating layer 105 in the first direction X1 may be equal to a width W2 of the third field insulating layer 107 in the first direction X1. In addition, a height H2 of the second field insulating layer 105 from a lower surface of the first fin pattern F11 may be equal to a height H2 of the third field insulating layer 107 from the lower surface of the first fin pattern F11. The second fin pattern F12 may be located between the second field insulating layer 105 and the third field insulating layer 107.

The first through fourth gates 250_1, 150_1, 150_2 and 250_2 may be formed in a direction intersecting corresponding fin patterns. The first through fourth gates 250_1, 150_1, 150_2 and 250_2 may extend along the second direction Y1.

Specifically, the first gate 250_1 may be formed on the first fin pattern F11 to intersect the first fin pattern F11. The second gate 150_1 may be formed on the second insulating layer 105. The third gate 150_2 may be formed on the third field insulating layer 107. The fourth gate 250_2 may be formed on the third fin pattern F13 to intersect the third fin pattern F13. The first through fourth gates 250_1, 150_1, 150_2 and 250_2 may be disposed parallel to each other and arranged at regular intervals.

For example, a distance P1 between the first gate 250_1 and the second gate 150_1 may be equal to a distance P1 between the second gate 150_1 and the third gate 150_2. Likewise, a distance P1 between the second gate 150_1 and the third gate 150_2 may be equal to a distance P1 between the third gate 150_2 and the fourth gate 250_2. That is, a plurality of gates may be arranged at equal pitches.

In the drawings, a first gate 250_1 intersecting the first fin pattern F11 is illustrated. However, this is merely for ease of description, and the number of first gates 250_1 is not limited to one. The same applies to the fourth gate 250_2 intersecting the third fin pattern F13.

More specifically, the second gate 150_1 may be formed on the second field insulating layer 105. In other words, the second gate 150_1 may be formed on the upper surface of the second field insulating layer 105 which protrudes from the first field insulating layer 103 and extend along the second direction Y1 intersecting the first fin pattern F11. However, the example embodiments of inventive concepts are not limited thereto.

Likewise, the third gate 150_2 may be formed on the third field insulating layer 107. The third gate 150_2 may be formed on the upper surface of the third field insulating layer 107 which protrudes from the first field insulating layer 103 and extend along the second direction Y1 intersecting the first fin pattern F11.

In some example embodiments of inventive concepts, the second gate 150_1 and the third gate 150_2 may operate as single diffusion breakers (SDBs). However, the example embodiments of inventive concepts are not limited thereto, and the second gate 150_1 and the third gate 150_2 disposed on the second field insulating layer 105 and the third field insulating layer 107 can be misaligned with the second field insulating layer 105 and the third field insulting layer 107, respectively.

Here, no gate may be formed between the second gate 150_1 and the third gate 150_2. In addition, the second gate 150_1 and the third gate 150_2 may be disposed most adjacent to each other. That is, an unnecessary dummy gate need not be formed between the second gate 150_1 and the third gate 150_2. Accordingly, since a dummy gate located between cells can be removed, the usable area of a chip can be increased, which, in turn, can increase the integration density and yield of semiconductor devices.

Each of the first through fourth gates 250_1, 150_1, 150_2 and 250_2 may include metal layers (MG1, MG2). For example, the first gate 250_1 may be formed by stacking two or more metal layers (MG1, MG2) as illustrated in the drawings. A first metal layer MG1 may control a work function, and a second metal layer MG2 may fill a space formed by the first metal layer MG1. The first metal layer MG1 may contain at least one of, but not limited to, TiN, WN, TiAl, TiAIN, TaN, TiC, TaC, TaCN, TaSiN, and combinations of the same. In addition, the second metal layer MG2 may contain at least one of, but not limited to, W, Al, Cu, Co, Ti, Ta, poly-Si, SiGe, and metal alloys.

The first through fourth gates 250_1, 150_1, 150_2 and 250_2 may be formed by, but not limited to, a replacement process (or a gate last process).

The first gate 250_1 may be formed on the first field insulating layer 103 and the first fin pattern F11 which protrudes further upward than the first field insulating layer 103.

Further, the upper surface of the second field insulating layer 105 and the upper surface of the third field insulating layer 107 are higher than the upper surface of the first field insulating layer 103. Accordingly, at least part of a bottom surface of the second gate 150_1 and at least part of a bottom surface of the third gate 150_2 may be higher than a bottom surface of the first gate 250_1.

The second gate 150_1 and the third gate 150_2 may be formed by, e.g., a replacement process. Therefore, an upper surface of the second gate 150_1 and an upper surface of the third gate 150_2 may lie in the same plane.

In FIG. 4A, a first gate insulating layer 255_1 may be formed between the first fin pattern F11 and the first gate 250_1. The first gate insulating layer 255_1 may be formed along the profile of the first fin pattern F11 which protrudes further upward than the first field insulating layer 103. In addition, the first gate insulating layer 255_1 may be disposed between the first gate 250_1 and the first field insulating layer 103.

Additionally, referring to FIG. 4B, an interfacial layer 121 may further be formed between the first gate insulating layer 255_1 and the first fin pattern F11. Although not illustrated in FIG. 5, the interfacial layer 121 may further be formed between the first gate insulating layer 255_1 and the first fin pattern F11 in FIG. 5.

In FIG. 4B, the interfacial layer 121 is formed along the profile of the first fin pattern F11 which protrudes further upward than the upper surface of the first field insulating layer 103. However, the example embodiments of inventive concepts are not limited thereto.

Depending on a method of forming the interfacial layer 121, the interfacial layer 121 can also extend along the upper surface of the first field insulating layer 103.

For ease of description, the example embodiments of inventive concepts will hereinafter be described using the drawings without the interfacial layer 121.

Gate insulating layers 255_1, 155_1, 155_2 and 255_2 may contain a high-k material having a higher dielectric constant than a silicon oxide layer. For example, the first gate insulating layer 255_1 may contain one or more of, but not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

First spacers 260_1 may be disposed on sidewalls of the first gate 250_1 extending along the second direction Y1. Second spacers 160_1 may be formed on sidewalls of the second gate 150_1. In addition, in the current example embodiment, any one of the second spacers 160_1 formed on both sidewalls of the second gate 150_1 may not be formed on the upper surface of the second field insulating layer 105. That is, any one of the second spacers 160_1 may be formed on the first fin pattern F11. However, the example embodiments of inventive concepts are not limited thereto. Likewise, third spacers 160_2 may be formed on sidewalls of the third gate 150_2, and any one of the third spacers 160_2 may be formed on the third fin pattern F13. However, the example embodiments of inventive concepts are not limited thereto.

The spacers 260_1, 160_1, 160_2 and 260_2 may contain at least one of, but not limited to, silicon nitride (SiN), silicon oxynitride (SiON), silicon oxide (SiO2), silicon oxycarbonitride (SiOCN), and combinations of the same.

A first source/drain region 140_1 may be formed in the first fin pattern F11 on a side of the first gate 250_1 and between the first gate 250_1 and the second gate 150_1.

A second source/drain region 140_2 may be formed in the second fin pattern F12 between the second gate 150_1 and the third gate 150_2.

A third source/drain region 140_3 may be formed in the third fin pattern F13 between the third gate 150_2 and the fourth gate 250_2 and on a side of the fourth gate 250_2.

In addition, a first semiconductor layer 111_1 which is part of the first fin pattern F11 may be located between the first source/drain region 140_1, which is adjacent to the second field insulating layer 105, and the second field insulating layer 105. Further, a second semiconductor layer 111_2 which is part of the second fin pattern F12 may be located between the second source/drain region 140_2, which is adjacent to the second field insulating layer 105, and the second field insulating layer 105. Likewise, a semiconductor layer may also be located on both sidewalls of the third field insulating layer 107. However, the example embodiments of inventive concepts are not limited thereto.

When the semiconductor device 1 according to an example embodiment is a p-channel metal oxide semiconductor (PMOS) transistor, the first source/drain region 140_1 may contain a compressive stress material. In an example, the compressive stress material may be a material (e.g., SiGe) having a greater lattice constant than Si. The compressive stress material can improve the mobility of carriers in a channel region by applying compressive stress to the first fin pattern F11.

On the other hand, when the semiconductor device 1 according to an example embodiment is an n-channel metal oxide semiconductor (NMOS) transistor, the first source/drain region 140_1 may contain the same material as the substrate 100 or a tensile stress material. In an example, when the substrate 100 is Si, the first source/drain region 140_1 may be Si or a material (e.g., SiC) having a smaller lattice constant than Si.

In addition, the first source/drain region 140_1 may be formed by doping the first fin pattern F11 with impurities.

The second source/drain region 140_2 and the third source/drain region 140_3 may be substantially identical to the first source/drain region 140_1 described above.

In addition, the first through third source/drain regions 140_1 through 140_3 may be, but are not limited to, elevated source/drain regions which are formed higher than the upper surfaces of the second field insulating layer 105 and the third field insulating layer 107.

An interlayer insulating film 190 may be formed on the first through third source/drain regions 140_1 through 140_3. In addition, the interlayer insulating film 190 may cover the first through fourth gates 250_1, 150_1, 150_2 and 250_2.

The interlayer insulating film 190 may contain one of, e.g., silicon oxide, silicon nitride, silicon oxynitride, and a low-k material. Examples of the low-k material may include, but not limited to, flowable oxide (FOX), tonen silazen (TOSZ), undoped silicate glass (USG), borosilicate glass (BSG), phosphosilicate glass (PSG), borophosphosilicate glass (BPSG), plasma enhanced tetraethylorthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SILK, polyimide, a porous polymeric material, and combinations of the same.

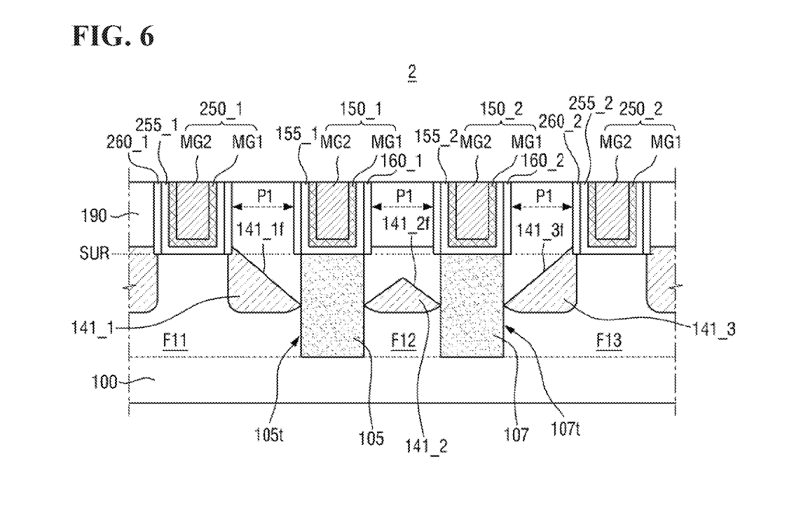

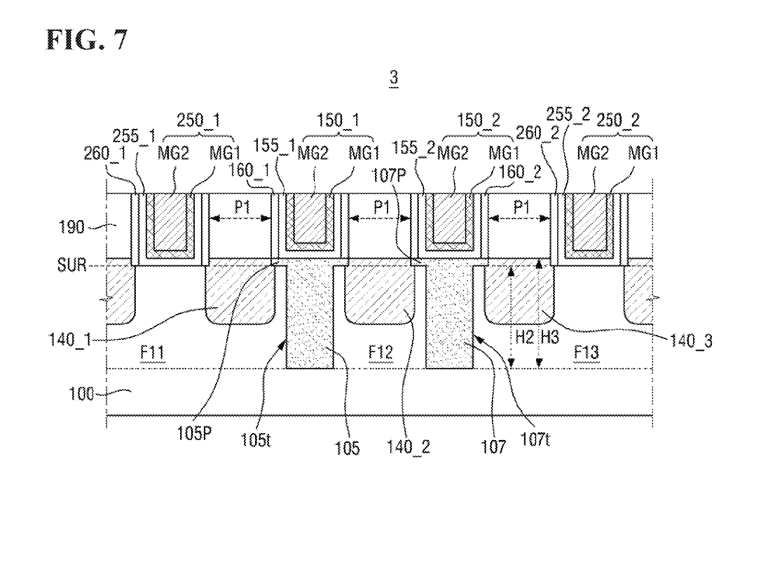

FIG. 6 illustrates a modified example 2 of the semiconductor device 1 of FIGS. 1A through 5. For simplicity, the current modified example 2 will hereinafter be described, focusing mainly on differences with the example embodiment described above with reference to FIGS. 1A through 5.

Referring to FIG. 6, in the modified example 2 of the semiconductor device 1 of FIGS. 1 through 5, a first source/drain region 141_1 and a second source/drain region 141_2 disposed on both sides of a second gate 150_1 may contact a second field insulating layer 105.

The first source/drain region 141_1 formed on a side of the second gate 150_1 may include a first facet 141_1f. The first facet 141_1f may begin from a sidewall of the second field insulating layer 105 which is lower than an upper surface SUR of a first fin pattern F11. Accordingly, a portion (the first semiconductor layer 111_1 of FIG. 5) of the first fin pattern F11 may not be interposed between the first source/drain region 141_1 formed on the side of the second gate 150_1 and the second field insulating layer 105.

In cross-sectional view, part of an interlayer insulating film 190 may be interposed between the sidewall of the second field insulating layer 105 and the first facet 141_1f of the first source/drain region 141_1.

Likewise, the second source/drain region 141_2 formed on the other side of the second gate 150_1 may include a second facet 141_2f. The second facet 141_2f may begin from a sidewall of the second field insulating layer 105 which is lower than an upper surface SUR of a second fin pattern F12. Accordingly, a portion (the second semiconductor layer 111_2 of FIG. 5) of the second fin pattern F12 may not be interposed between the second source/drain region 141_2 formed on the other side of the second gate 150_1 and the second field insulating layer 105.

In cross-sectional view, part of the interlayer insulating film 190 may be interposed between the sidewall of the second field insulating layer 105 and the second facet 141_2f of the second source/drain region 141_2.

However, example embodiments of inventive concepts are not limited thereto, and, unlike the illustration in the drawing, one of the first and second source/drain regions 141_1 and 141_2 adjacent to the second gate 150_1 may not include a facet.

Likewise, the second source/drain region 141_2 and a third source/drain region 141_3 disposed on both sides of a third gate 150_2 may contact a third field insulating layer 107. However, the example embodiments of inventive concepts are not limited thereto.

FIG. 7 illustrates another modified example 3 of the semiconductor device 1 of FIGS. 1A through 5. For simplicity, the current modified example 3 will hereinafter be described, focusing mainly on differences with the example embodiment described above with reference to FIGS. 1A through 5.

Referring to FIG. 7, in the modified example 3 of the semiconductor device 1 of FIGS. 1A through 5, a second field insulating layer 105 may include a first protrusion 105P which extends along an upper surface SUR of a first fin pattern F11. In addition, the first protrusion 105P may extend along an upper surface SUR of a second fin pattern F12. The second insulating layer 105 including the first protrusion 105P may be, e.g., T-shaped.

At least part of a second gate 150_1 may be formed on the first protrusion 105P. At least part of the second gate 150_1 may intersect the first protrusion 105P.

A third field insulating layer 107 may include a second protrusion 107P which extends along the upper surface SUR of the second fin pattern F12 and an upper surface SUR of a third fin pattern F13. The third field insulating layer 107 including the second protrusion 107P may be, e.g., T-shaped.

Second spacers 160_1 formed on both sidewalls of the second gate 150_1 may be formed on the second field insulating layer 105 including the first protrusion 105P. Third spacers 160_2 formed on both sidewalls of a third gate 150_2 may be formed on the third field insulating layer 107 including the second protrusion 107P.

Here, a lower surface of the second gate 150_1 and a lower surface of the third gate 150_2 may be, but is not limited to, higher than the upper surface SUR of the first fin pattern F11.

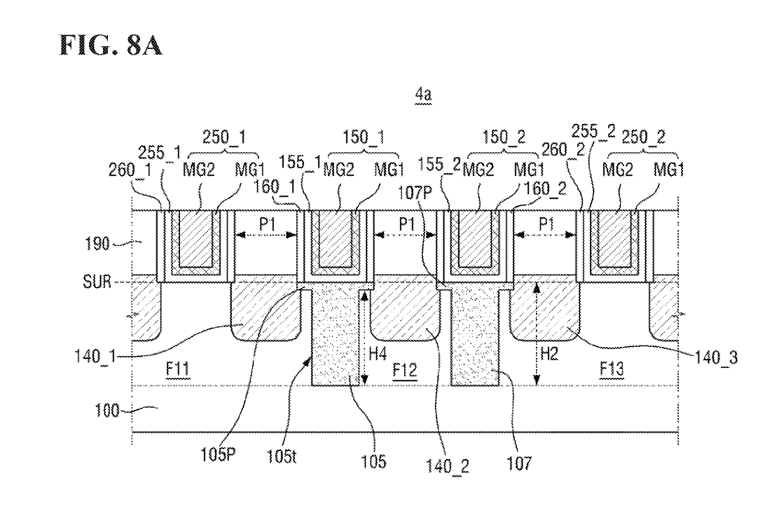

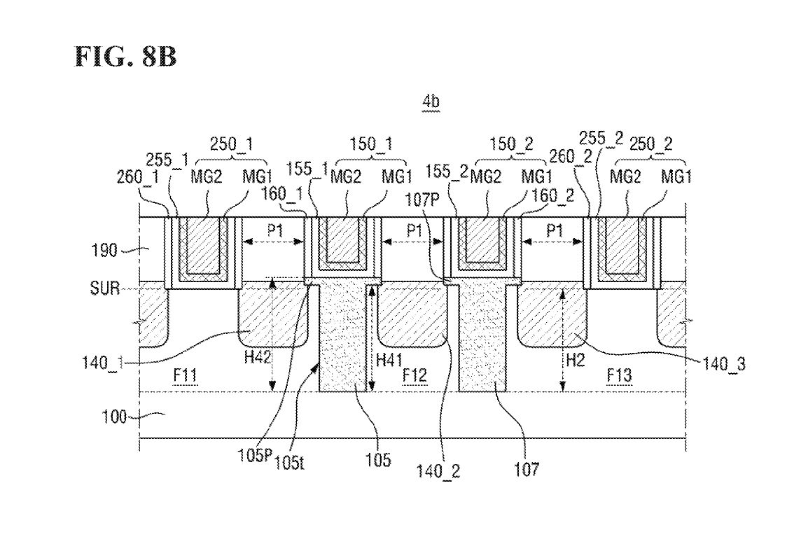

FIG. 8A illustrates another modified example 4a of the semiconductor device 1 of FIGS. 1A through 5. FIG. 8B illustrates another modified example 4b of the semiconductor device 1 of FIGS. 1A through 5. For simplicity, the current modified examples 4a and 4b will hereinafter be described, focusing mainly on differences with the example embodiments described above with reference to FIGS. 1A through 5 and 7.

Referring to FIG. 8A, an upper surface of a portion of a first fin pattern F11 which is overlapped by a second gate 150_1 may be lower than an upper surface of a portion of the first fin pattern F11 which is overlapped by a first gate 250_1.

Specifically, a height H4 of the portion of the first fin pattern F11 which is overlapped by the second gate 150_1 may be lower than a height H2 of the portion of the first fin pattern F11 which is overlapped by the first gate 250_1.

In other words, the upper surface of the portion of the first fin pattern F11 which is overlapped by the second gate 150_1 may be more recessed than that of the other portion of the first fin pattern F11.

A second field insulating layer 105 may include a first protrusion 105P between the second gate 150_1 and the first fin pattern F11. The first protrusion 105P may also be formed between the second gate 150_1 and a second fin pattern F12.

Since the upper surface of the portion of the first fin pattern F11 which is overlapped by the second gate 150_1 is recessed, a first source/drain region 140_1 formed between the second gate 150_1 and the first gate 250_1 may have an asymmetrical shape.

Further, a third field insulating layer 107 may include a second protrusion 107P.

A height H4 of a portion of the second fin pattern F12 or a portion of a third fin pattern F13 which is overlapped by the second protrusion 107P of the third field insulating layer 107 may be lower than a height H2 of a portion of the third fin pattern F13 which is overlapped by a fourth gate 250_2.

In FIG. 8A, an upper surface of the second field insulating layer 105 and an upper surface of the third field insulating layer 107 lie in the same plane with upper surfaces SUR of the first through third fin patterns F11 through F13. However, this is merely for ease of description, and example embodiments of inventive concepts are not limited thereto.

Referring to FIG. 8B, an upper surface of a portion of a first fin pattern F11 which is overlapped by a second gate 150_1 may be higher than an upper surface of a portion of the first fin pattern F11 which is overlapped by a first gate 250_1.

Specifically, a height H41 of the portion of the first fin pattern F11 which is overlapped by the second gate 150_1 may be higher than a height H2 of the portion of the first fin pattern F11 which is overlapped by the first gate 250_1.

In other words, the upper surface of the portion of the first fin pattern F11 which is overlapped by the second gate 150_1 may protrude further upward than an upper surface SUR of the first fin pattern F11.

A second field insulating layer 105 may include a first protrusion 105P between the second gate 150_1 and the first fin pattern F11. Accordingly, since the upper surface of the portion of the first fin pattern F11 which is overlapped by the second gate 150_1 is recessed, a first source/drain region 140_1 formed between the second gate 150_1 and the first gate 250_1 may have an asymmetrical shape.

Further, a third field insulating layer 107 may include a second protrusion 107P which protrudes onto an upper surface of a second fin pattern F12 and an upper surface of a third fin pattern F13.

A height of a portion of the second fin pattern F12 or a portion of the third fin pattern F13 which is overlapped by the second protrusion 107P of the third field insulating layer 107 may be higher than a height of a portion of the third fin pattern F13 which is overlapped by a fourth gate 250_2.

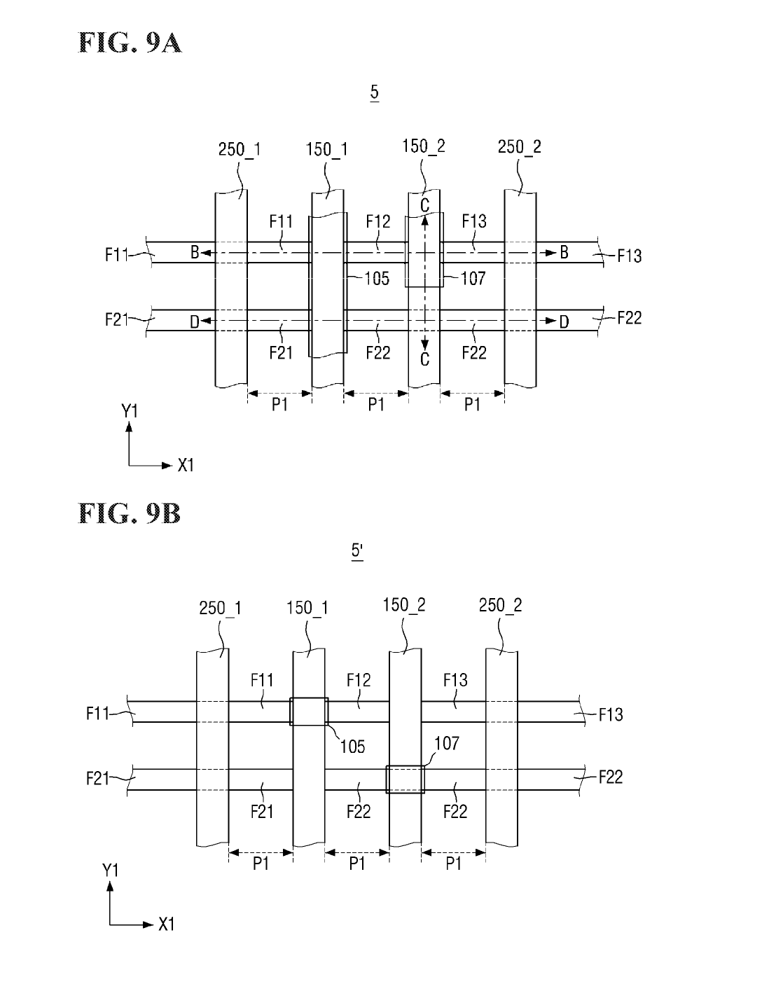

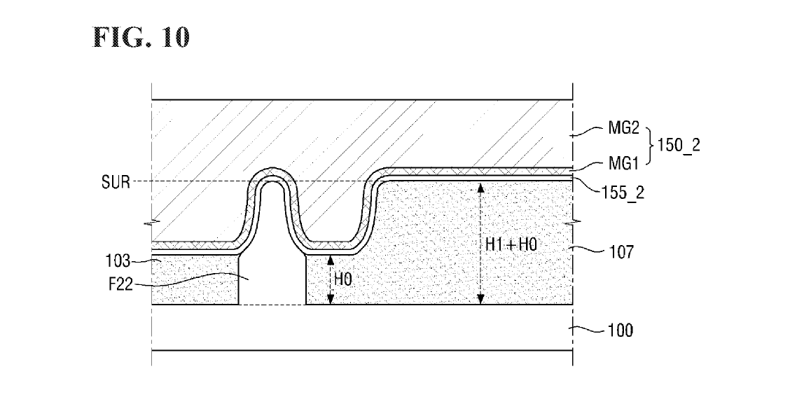

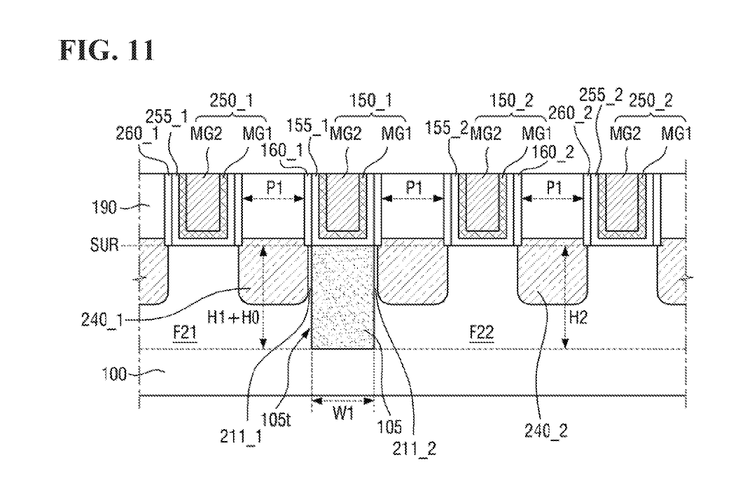

FIGS. 9A and 9B are a plan view of a semiconductor device 5 according to different example embodiments of inventive concepts. FIG. 10 is a cross-sectional view taken along the line C-C of FIG. 9A. FIG. 11 is a cross-sectional view taken along the line D-D of FIG. 9A. For simplicity, a redundant description of elements identical to those of the previous example embodiments will be omitted, and the current example embodiment will hereinafter be described, focusing mainly on differences with the previous example embodiments.

Referring to FIGS. 9A through 11, the semiconductor device 5 according to the current example embodiment may include first through third field insulating layers 103, 105 and 107, first through fifth fin patterns F11 through F13, F21 and F22, and first through fourth gates 250_1, 150_1, 150_2 and 250_2.

The first through third fin patterns F11 through F13 may protrude from a substrate 100. The first through third fin patterns F11 through F13 may extend along a first direction X1. The first through third fin patterns F11 through F13 may be formed side by side with each other in a lengthwise direction. That is, the first through third fin patterns F11 through F13 may lie on the same line. In addition, the first through third fin patterns F11 through F13 may be separated from each other.

Likewise, the fourth and fifth fin patterns F21 and F22 may protrude from the substrate 100. The fourth and fifth fin patterns F21 and F22 may extend along the first direction X1. The fourth and fifth fin patterns F21 and F22 may be formed side by side with each other in the lengthwise direction. That is, the fourth and fifth fin patterns F21 and F22 may lie on the same line. In addition, the fourth and fifth fin patterns F21 and F22 may be separated from each other. Here, the first through third fin patterns F11 through F13 may be separated from the fourth and fifth fin patterns F21 and F22.

The first through third field insulating layers 103, 105 and 107 may be formed on the substrate 100 and disposed around the first through fifth fin patterns F11 through F13, F21 and F22.

Specifically, the first field insulating layer 103 may extend along the first direction X1 and cover long sides of the first through fifth fin patterns F11 through F13, F21 and F22.

The second field insulating layer 105 may extend along a second direction Y1. That is, the second field insulating layer 105 may extend in a direction intersecting the first through fifth fin patterns F11 through F13, F21 and F22. The second field insulating layer 105 may be formed between the first fin pattern F11 and the second fin pattern F12 and between the fourth fin pattern F21 and the fifth fin pattern F22. Here, the second field insulating layer 105 may extend in the form of a straight line.

The third field insulating layer 107 may extend along the second direction Y1. However, the third field insulating layer 107 may be formed only between the second fin pattern F12 and the third fin pattern F13 and may not overlap the fifth fin pattern F22.

The first through fourth gates 250_1, 150_1, 150_2 and 250_2 may extend along the second direction Y1 intersecting corresponding fin patterns.

Specifically, the first gate 250_1 may intersect the first fin pattern F11 and the fourth fin pattern F21. The second gate 150_1 may be formed on the second field insulating layer 105. The third gate 150_2 may be formed on the third field insulating layer 107 and intersect the fifth fin pattern F22. The fourth gate 250_2 may intersect the third fin pattern F13 and the fifth fin pattern F22. The first through fourth gates 250_1, 150_1, 150_2 and 250_2 may be disposed parallel to each other and arranged at equal pitches P1.

A cross-sectional view taken along the line B-B of FIG. 9A is identical to the cross-sectional view of FIG. 5 described above, and thus a detailed description thereof is omitted.

Referring to FIGS. 9A-9B, the semiconductor devices 5 and 5′, some example embodiments may include the second and the third field insulating layers 105 and 107, the first through the fifth fin patterns F11 through F13, F21 and F22, and the first through the fourth gates 250_1, 150_1, 150_2 and 250_2.

The second and the third field insulating layers 105 and 107 of FIG. 9A may extend longer in the second direction Y1 than the second and the third field insulating layers 105 and 107 of FIG. 9B. In other words, in FIG. 9B, the size of the second field insulating layer 105 (and/or the third insulating layer 107) may be reduced as compared to FIG. 9A.

FIG. 10 is a cross-sectional view taken along a direction C-C in which the third field insulating layer 107 extends. Referring to FIG. 10, the third field insulating layer 107 may be disposed between the second fin pattern F12 and the third fin pattern F13, and the first field insulating layer 103 may be disposed around the fifth fin pattern F22.

Here, the first field insulating layer 103 may have a height of HO, and the third field insulating layer 107 may have a height of H0+H1. That is, the third field insulating layer 107 may be higher than the first field insulating layer 103 by H1. A height of an upper surface of the third field insulating layer 107 may be, but is not limited to, equal to a height of an upper surface SUR of the fifth fin pattern F22.

Referring to FIG. 11, the first gate 250_1 may be formed on the fourth fin pattern F21 to intersect the fourth fin pattern F21. The second gate 150_1 may be formed on the second field insulating layer 105. The third gate 150_2 and the fourth gate 250_2 may be formed on the fifth fin pattern F22 to intersect the third fin pattern F13. The first through fourth gates 250_1, 150_1, 150_2 and 250_2 may be disposed parallel to each other and arranged at regular intervals.

For example, a distance P1 between the first gate 250_1 and the second gate 150_1 may be equal to a distance P1 between the second gate 150_1 and the third gate 150_2. Likewise, a distance P1 between the second gate 150_1 and the third gate 150_2 may be equal to a distance P1 between the third gate 150_2 and the fourth gate 250_2. That is, a plurality of gates may be arranged at equal pitches.

In the drawings, one first gate 250_1 intersecting the first fin pattern F11 is illustrated. However, this is merely for ease of description, and the number of first gates 250_1 is not limited to one.

Specifically, the second gate 150_1 may be formed on the second field insulating layer 105. In other words, the second gate 150_1 may be formed on an upper surface of the second field insulating layer 105 which protrudes from the first field insulating layer 103 and extend along the second direction Y1 intersecting the first fin pattern F11. However, the example embodiments of inventive concepts are not limited thereto.

In some embodiments of the present inventive concepts, the second gate 150_1 may operate as a Single Diffusion Breaker (SDB). However, example embodiments of inventive concepts are not limited thereto, and the second gate 150_1 disposed on the second field insulating layer 105 can be misaligned with the second field insulating layer 105.

Here, no gate may be formed between the second gate 150_1 and the third gate 150_2. In addition, the second gate 150_1 and the third gate 150_2 may be disposed most adjacent to each other. That is, an unnecessary dummy gate need not be formed between the second gate 150_1 and the third gate 150_2. Accordingly, dummy gates located between cells can be reduced.

In addition, the third gate 150_2 disposed on the fifth fin pattern F22 may operate as a normal transistor. That is, while the third gate 150_2 disposed on the third field insulating layer 107 operates as a dummy gate, the third gate 150_2 intersecting the fifth fin pattern F22 may operate as a gate of a normal transistor. Therefore, elevated source/drain regions may be formed on both sides of a region in which the third gate 150_2 and the fifth fin pattern F22 intersect each other, and a channel region may be formed in the fifth fin pattern F22 under the third gate 150_2. Accordingly, this can increase the usable area of a chip and the integration density of semiconductor devices according to example embodiments of inventive concepts.

A fourth source/drain region 240_1 may be formed in the fourth fin pattern F21 on a side of the first gate 250_{—} 1 and between the first gate 250_1 and the second gate 150_1.

A fifth source/drain region 240_2 may be formed in the fifth fin pattern F22 between the second gate 150_1 and the third gate 150_2 and between the third gate 150_2 and the fourth gate 250_2.

The fourth and fifth source/drain regions 240_1 and 240_2 may be, but are not limited to, elevated source/drain regions whose upper surfaces are higher than those of the second field insulating layer 105 and the third field insulating layer 107.

An interlayer insulating film 190 may be formed on the fourth and fifth source/drain regions 240_1 and 240_2. In addition, the interlayer insulating film 190 may surround the first through fourth gates 250_1, 150_1, 150_2 and 250_2.

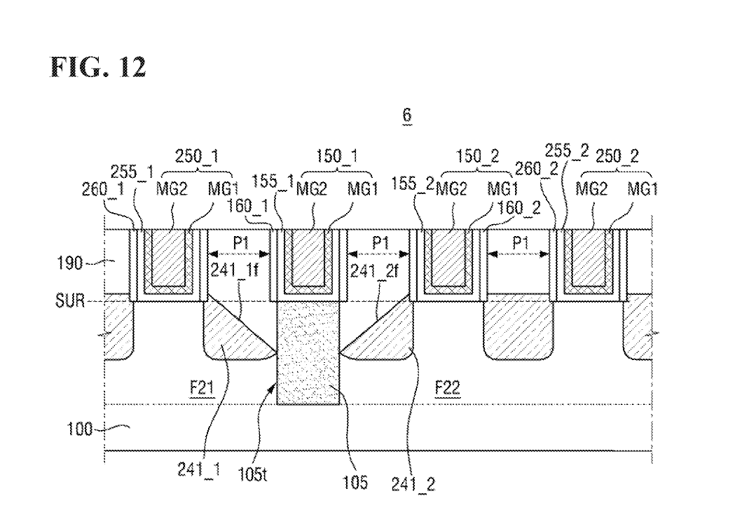

FIG. 12 illustrates a modified example 6 of the semiconductor device 5 of FIGS. 9A through 11. For simplicity, the current modified example 6 will hereinafter be described, focusing mainly on differences with the example embodiment described above with reference to FIGS. 9A through 11.

FIG. 12 is a cross-sectional view taken along the line D-D of FIG. 9A. In the modified example 6 of the semiconductor device 5 of FIGS. 9A through 11, a cross-sectional view taken along the line B-B of FIG. 9A is identical to the cross-sectional view of FIG. 6 described above, and thus a detailed description thereof will be omitted.

Referring to FIG. 12, a fourth source/drain region 241_1 and a fifth source/drain region 241_2 disposed on both sides of a second gate 150_1 may contact a second field insulating layer 105.

The fourth source/drain region 241_1 formed on a side of the second gate 150_1 may include a first facet 241_1f. The first facet 241_1f may begin from a sidewall of the second field insulating layer 105 which is lower than an upper surface SUR of a fourth fin pattern F21. Accordingly, a portion (a first semiconductor layer 211_1 of FIG. 11) of the fourth fin pattern F21 need not be interposed between the fourth source/drain region 241_1 formed on the side of the second gate 150_1 and the second field insulating layer 105.

In cross-sectional view, part of an interlayer insulating film 190 may be interposed between the sidewall of the second field insulating layer 105 and the first facet 241_1f of the fourth source/drain region 241_1.

Likewise, the fifth source/drain region 241_2 formed on the other side of the second gate 150_1 may include a second facet 241_2f. The second facet 241_2f may begin from a sidewall of the second field insulating layer 105 which is lower than an upper surface SUR of a fifth fin pattern F22. Accordingly, a portion (a second semiconductor layer 211_2 of FIG. 11) of the fifth fin pattern F22 need not be interposed between the fifth source/drain region 241_2 formed on the other side of the second gate 150_1 and the second field insulating layer 105.

In cross-sectional view, part of the interlayer insulating film 190 may be interposed between the sidewall of the second field insulating layer 105 and the second facet 241_2f of the fifth source/drain region 241_2.

However, the example embodiments of inventive concepts are not limited thereto, and, unlike the illustration in the drawing, one of the fourth and fifth source/drain regions 241_1 and 241_2 adjacent to the second gate 150_1 may not include a facet.

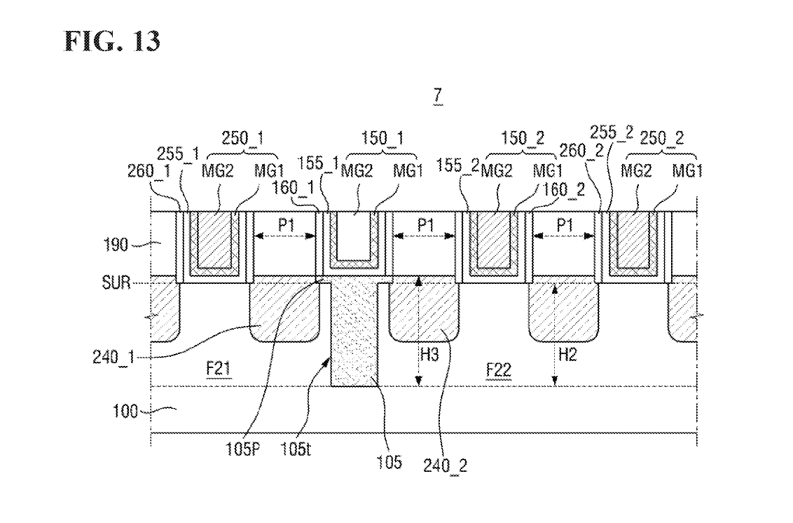

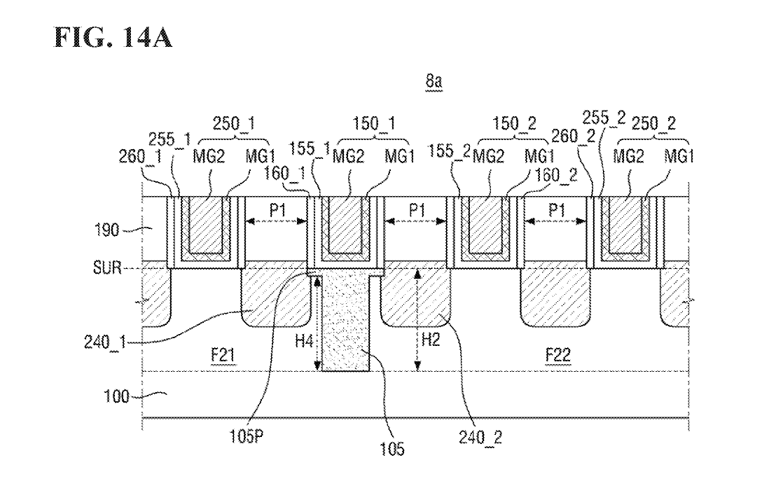

FIG. 13 illustrates another modified example 7 of the semiconductor device 5 of FIGS. 9A through 11. For simplicity, the current modified example 7 will hereinafter be described, focusing mainly on differences with the example embodiment described above with reference to FIGS. 9A through 11.

FIG. 13 is a cross-sectional view taken along the line D-D of FIG. 9A. In the modified example 7 of the semiconductor device 5 of FIGS. 9A through 11, a cross-sectional view taken along the line B-B of FIG. 9A is identical to the cross-sectional view of FIG. 6 described above, and thus a detailed description thereof will be omitted.

Referring to FIG. 13, a second field insulating layer 105 may include a first protrusion 105P which extends along an upper surface SUR of a fourth fin pattern F21. In addition, the first protrusion 105P may extend along an upper surface SUR of a fifth fin pattern F12. The second insulating layer 105 including the first protrusion 105P may be, e.g., T-shaped.

At least part of a second gate 150_1 may be formed on the first protrusion 105P. At least part of the second gate 150_1 may intersect the first protrusion 105P. For example, part of the second gate 150_1 may be formed on the first protrusion 105P.

Here, a lower surface of the second gate 150_1 may be, but is not limited to, higher than the upper surface SUR of the fourth fin pattern F21.

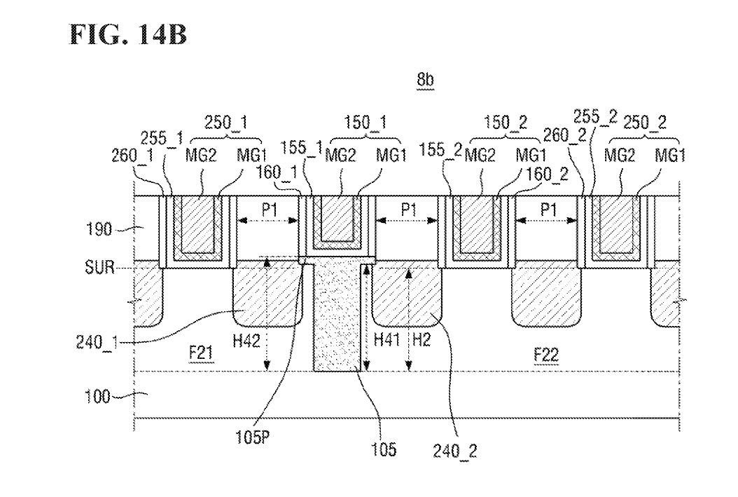

FIG. 14A illustrates another modified example 8a of the semiconductor device 5 of FIGS. 9A through 11. FIG. 14B illustrates another modified example 8b of the semiconductor device 5 of FIGS. 9A through 11. For simplicity, the current modified examples 8a and 8b will hereinafter be described, focusing mainly on differences with the example embodiment described above with reference to FIGS. 9A through 11.

FIGS. 14A and 14B are cross-sectional views taken along the line D-D of FIG. 9A. In the modified examples 8a and 8b of the semiconductor device 5 of FIGS. 9A through 11, cross-sectional views taken along the line B-B of FIG. 9A are identical to the cross-sectional views of FIGS. 8A and 8B described above, and thus a detailed description thereof will be omitted.

Referring to FIGS. 14A and 14B, an upper surface of a portion of a fourth fin pattern F21 which is overlapped by a second gate 150_1 may be lower than an upper surface of a portion of the fourth fin pattern F21 which is overlapped by a first gate 250_1.

Specifically, a height H4 of the portion of the fourth fin pattern F21 which is overlapped by the second gate 150_1 may be lower than a height H2 of the portion of the fourth fin pattern F21 which is overlapped by the first gate 250_1.

In other words, the upper surface of the portion of the fourth fin pattern F21 which is overlapped by the second gate 150_1 may be more recessed than that of the other portion of the fourth fin pattern F21.

Since the upper surface of the portion of the fourth fin pattern F21 which is overlapped by the second gate 150_1 is recessed, a fourth source/drain region 240_1 formed between the second gate 150_1 and the first gate 250_1 may have an asymmetrical shape.

In FIG. 14A, an upper surface of a second field insulating layer 105 lies in the same plane with upper surfaces SUR of the fourth and fifth fin patterns F21 and F22. However, this is merely for ease of description, and the example embodiments of inventive concepts are not limited thereto.

Referring to FIG. 14B, an upper surface of a portion of a fourth fin pattern F21 which is overlapped by a second gate 150_1 may be higher than an upper surface of a portion of the fourth fin pattern F21 which is overlapped by a first gate 250_1.

Specifically, a height H41 of the portion of the fourth fin pattern F21 which is overlapped by the second gate 150_1 may be higher than a height H2 of the portion of the fourth fin pattern F21 which is overlapped by the first gate 250_1.

In other words, the upper surface of the portion of the fourth fin pattern F21 which is overlapped by the second gate 150_1 may protrude further upward than an upper surface SUR of the fourth fin pattern F21.

Likewise, since the upper surface of the portion of the fourth fin pattern F21 which is overlapped by the second gate 150_1 is recessed, a fourth source/drain region 240_1 formed between the second gate 150_1 and a first gate 250_1 may have an asymmetrical shape.

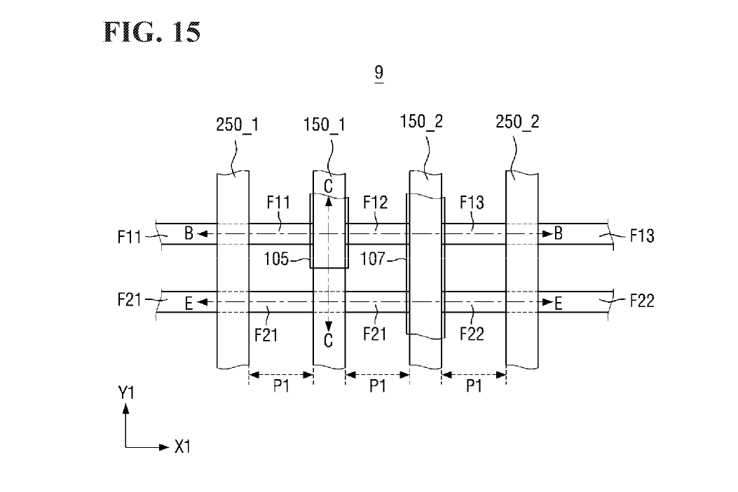

FIG. 15 illustrates a semiconductor device 9 according to other example embodiments of inventive concept.

Referring to FIG. 15, a cross-sectional view taken along the line B-B of FIG. 15 is identical to those of FIGS. 5 through 8B described above, and thus a detailed description thereof is omitted.

A cross-sectional view taken along the line E-E of FIG. 15 is similar to those of FIGS. 11 through 14B described above. However, a second field insulating layer 105 may be formed only between a first fin pattern F11 and a second fin pattern F12 and may not overlap a fourth fin pattern F21.

In addition, a third field insulting layer 107 may be formed between the second fin pattern F12 and a third fin pattern F13 and between the fourth fin pattern F21 and a fifth fin pattern F22. Here, the third field insulating layer 107 may extend in the form of a straight line.

Accordingly, the cross-sectional view taken along the line E-E of FIG. 15 may be substantially identical to horizontal symmetrical versions of the cross-sectional views of FIGS. 11 through 14 described above, and thus a detailed description thereof is omitted.

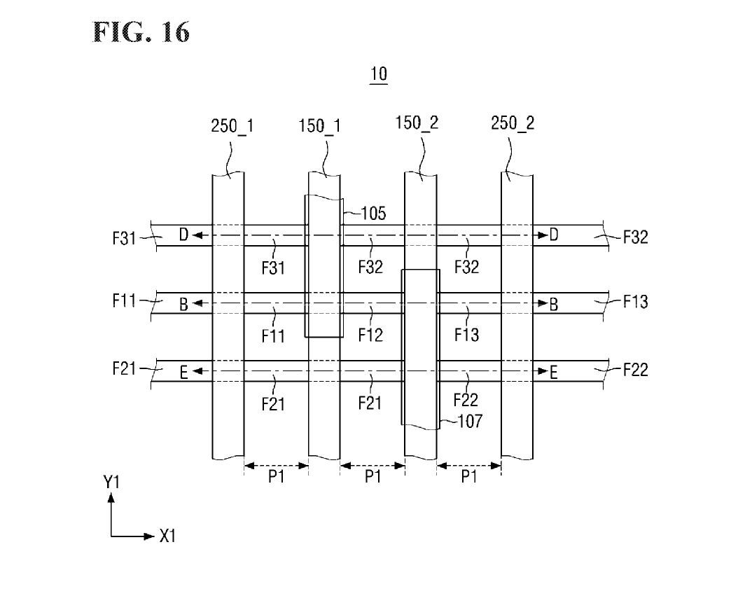

FIG. 16 illustrates a semiconductor device 10 according to another example embodiment of inventive concept.

Referring to FIG. 16, in the semiconductor device 10 of the example embodiments of inventive concepts, a second field insulating layer 105 is formed between a first fin pattern F11 and a second fin pattern F12 and between a sixth fin pattern F31 and a seventh fin pattern F32. A third field insulating layer 107 is formed between the second fin pattern F12 and a third fin pattern F13 and between a fourth fin pattern F21 and a fifth fin pattern F22.

A cross-sectional view taken along the line B-B of FIG. 16 is identical to the cross-sectional views of FIGS. 5 through 8B described above, and thus a detailed description thereof is omitted. A cross-sectional view taken along the line D-D of FIG. 16 is identical to the cross-sectional views of FIGS. 11 through 14B described above, and thus a detailed description thereof is omitted. In addition, a cross-sectional view taken along the line E-E of FIG. 16 is substantially identical to horizontally symmetrical versions of the cross-sectional views of FIGS. 11 through 14B described above, and thus a detailed description thereof is omitted.

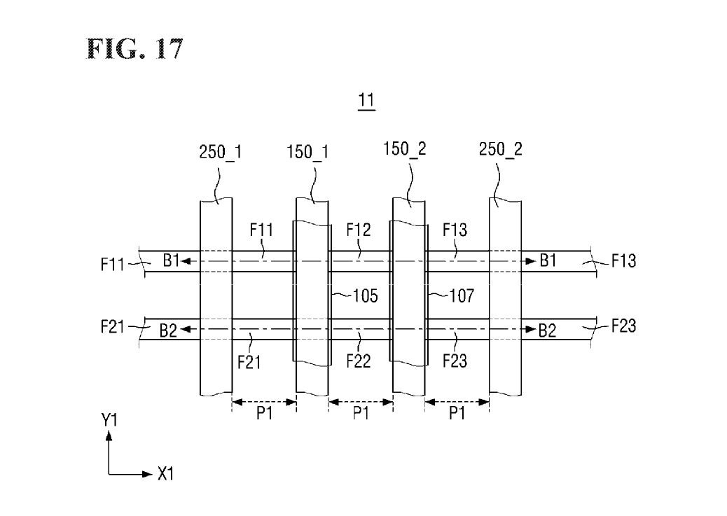

FIG. 17 illustrates a semiconductor device 11 according to another example embodiment of inventive concepts.

Referring to FIG. 17, in the semiconductor device 11 of inventive concepts, a second field insulating layer 105 is formed between a first fin pattern F11 and a second fin pattern F12 and between a fourth fin pattern F21 and a fifth fin pattern F22. A third field insulating layer 107 is formed between the second fin pattern F12 and a third fin pattern F13 and between the fifth fin pattern F22 and a sixth fin pattern F23.

Cross-sectional views taken along the lines B1-B1 and B2-B2 of FIG. 17 are identical to the cross-sectional views of FIGS. 5 through 8B described above, and thus a detailed description thereof is omitted.

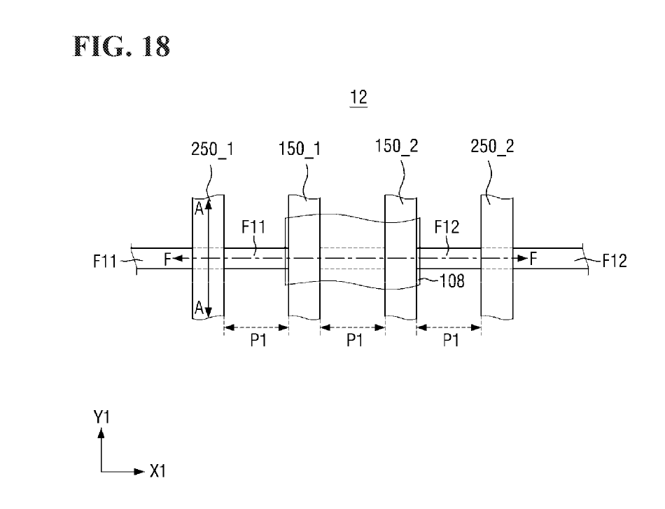

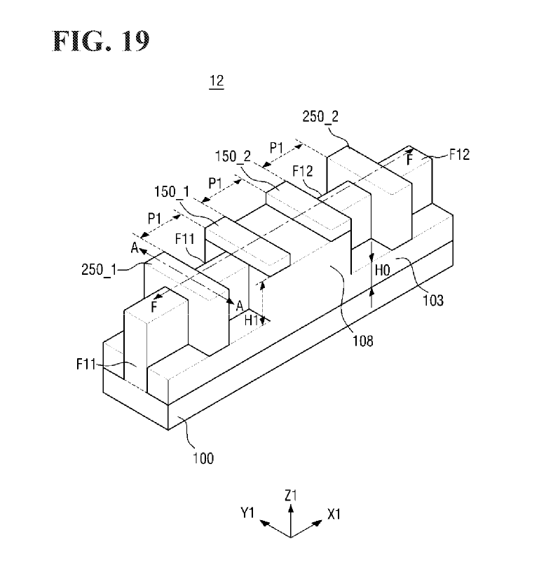

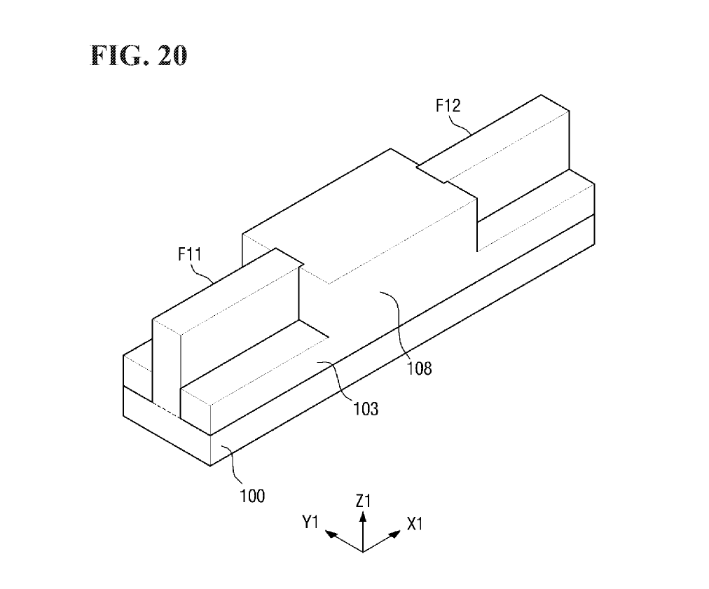

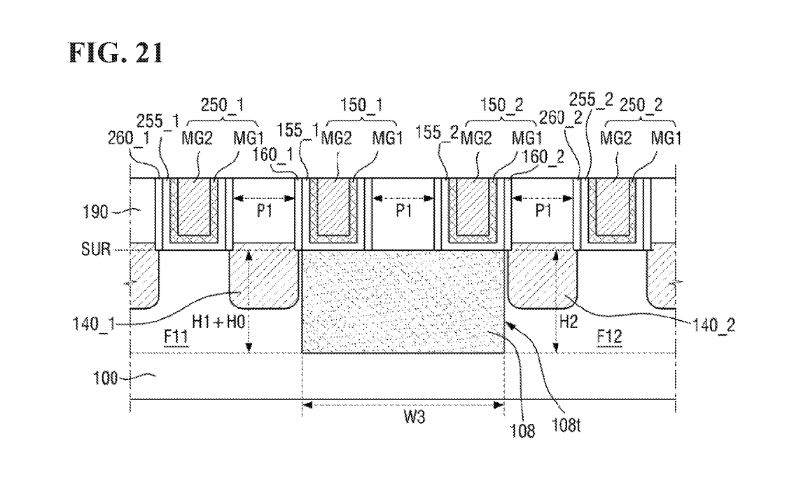

FIGS. 18 and 19 respectively are plan and perspective views of a semiconductor device 12 according to other example embodiments of inventive concepts. FIG. 20 is a partial perspective view of fin patterns and field insulating layers of the semiconductor device 12 of FIGS. 18 and 19. FIG. 21 is a cross-sectional view taken along the line F-F of FIGS. 18 and 19.

Referring to FIGS. 18 through 21, the semiconductor device 12 according to the current example embodiment may include first and second field insulating layers 103 and 108, first and second fin patterns F11 and F12, and first through fourth gates 250_1, 150_1, 150_2 and 250_2.

Here, the first and second fin patterns F11 and F12 may protrude from a substrate 100. The first and second fin patterns F11 and F12 may extend along a first direction X1. The first and second fin patterns F11 and F12 may be formed side by side with each other in a lengthwise direction. That is, the first and second fin patterns F11 and F12 may lie on the same line. In addition, the first and second fin patterns F11 and F12 may be separated from each other.

A first trench 103t may be formed around the first and second fin patterns F11 and F12. The first trench 103t may expose long sides of the first and second fin patterns F11 and F12.

A second trench 108t may be formed between the first fin pattern F11 and the second fin pattern F12. The second trench t may expose a short side of the first fin pattern F11 and a short side of the second fin pattern F12. That is, the second trench 108t may be disposed between the facing short sides of the first fin pattern F11 and the second fin pattern F12.

The first field insulating layer 103 and the second field insulating layer 108 may be formed on the substrate 100 and disposed around the first and second fin patterns F11 and F12.

Specifically, the first field insulating layer 103 may extend along the first direction X1 and cover the long sides of the first and second fin patterns F11 and F12. In addition, the first field insulating layer 103 may partially fill the first trench 103t.

The second field insulating layer 108 may be formed between the first fin pattern F11 and the second fin pattern F12. The second field insulating layer 108 may cover an end of the first fin pattern F11 and an end of the second fin pattern F12. In addition, the second field insulating layer 108 may completely fill the second trench 108t.

Here, an upper surface of the second field insulating layer 108 may protrude further upward than an upper surface of the first field insulating layer 103. For example, the first field insulating layer 108 may have a height of HO, and the second field insulating layer 108 may have a height of H0+H1. That is, the second field insulating layer 108 may be higher than the first field insulating layer 103 by H1.

In addition, the upper surface of the second field insulating layer 108 may lie in the same plane with an upper surface SUR of the first fin pattern F11, but the example embodiments of inventive concepts are not limited thereto.

In addition, a width W3 of the second field insulating layer 108 measured in the first direction X1 may be greater than a distance P1 between the second gate 150_1 and the third gate 150_2.

The first through fourth gates 250_1, 150_1, 150_2 and 250_2 may be formed in a direction intersecting corresponding fin patterns. The first through fourth gates 250_1, 150_1, 150_2 and 250_2 may extend along a second direction Y1.

Specifically, the first gate 250_1 may be formed on the first fin pattern F11 to intersect the first fin pattern F11. The second gate 150_1 may be formed on the second insulating layer 108 on one side. The third gate 150_2 may be formed on the second field insulating layer 108 on the other side. The fourth gate 250_2 may be formed on the second fin pattern F12 to intersect the second fin pattern F12. The first through fourth gates 250_1, 150_1, 150_2 and 250_2 may be disposed parallel to each other and arranged at regular intervals.

For example, a distance P1 between the first gate 250_1 and the second gate 150_1 may be equal to a distance P1 between the second gate 150_1 and the third gate 150_2. Likewise, a distance P1 between the second gate 150_1 and the third gate 150_2 may be equal to a distance P1 between the third gate 150_2 and the fourth gate 250_2. That is, a plurality of gates may be arranged at equal pitches.

In the drawings, one first gate 250_1 intersecting the first fin pattern F11 is illustrated. However, this is merely for ease of description, and the number of first gates 250_1 is not limited to one. The same applies to the fourth gate 250_2 intersecting the third fin pattern F13.

More specifically, the second gate 150_1 and the third gate 150_2 may be formed on the second field insulating layer 108. In other words, the second gate 150_1 and the third gate 150_2 may be formed on the upper surface of the second field insulating layer 105 which protrudes from the first field insulating layer 103.

In some example embodiments of inventive concepts, both the second gate 150_1 and the third gate 150_2 may be disposed on the second field insulating layer 108 and operate as dual diffusion breakers (DDBs). However, the example embodiments of inventive concepts are not limited thereto.

Here, no gate may be formed between the second gate 150_1 and the third gate 150_2. In addition, the second gate 150_1 and the third gate 150_2 may be disposed most adjacent to each other. That is, an unnecessary dummy gate may not be formed between the second gate 150_1 and the third gate 150_2. Accordingly, since dummy gates located between cells can be reduced, the usable area of a chip can be increased, which, in turn, can increase the integration density and yield of semiconductor devices.

Second spacers 160_1 may be formed on sidewalls of the second gate 150_1. In addition, in the current example embodiment, any one of the second spacers 160_1 formed on both sidewalls of the second gate 150_1 may not be formed on the upper surface of the second field insulating layer 108. That is, any one of the second spacers 160_1 may be formed on the first fin pattern F11. However, the example embodiments of inventive concepts are not limited thereto. Likewise, third spacers 160_2 may be formed on sidewalls of the third gate 150_2, and any one of the third spacers 160_2 may be formed on the second fin pattern F12. However, the example embodiments of inventive concepts are not limited thereto.

A first source/drain region 140_1 may be formed in the first fin pattern F11 on a side of the first gate 250_1 and between the first gate 250_1 and the second gate 150_1.

A second source/drain region 140_2 may be formed in the second fin pattern F12 between the third gate 150_2 and the fourth gate 250_2 and on a side of the fourth gate 250_2.

When the semiconductor device 12 according to the current example embodiment is a PMOS transistor, the first and second source/drain regions 140_1 and 140_2 may contain a compressive stress material. In an example, the compressive stress material may be a material (e.g., SiGe) having a greater lattice constant than Si. The compressive stress material can improve the mobility of carriers in a channel region by applying compressive stress to the first fin pattern F11.

On the other hand, when the semiconductor device 12 according to the current example embodiment is an NMOS transistor, the first and second source/drain regions 140_1 and 140_2 may contain the same material as the substrate 100 or a tensile stress material. In an example, when the substrate 100 is Si, the first and second source/drain regions 140_1 and 140_2 may be Si or a material (e.g., SiC) having a smaller lattice constant than Si.

The first and second source/drain regions 140_1 and 140_2 may be, but are not limited to, elevated source/drain regions whose upper surfaces are higher than that of the second field insulating layer 108.

An interlayer insulating film 190 may be formed on the first and second source/drain regions 140_1 and 140_2. In addition, the interlayer insulating film 190 may surround the first through fourth gates 250_1, 150_1, 150_2 and 250_2.

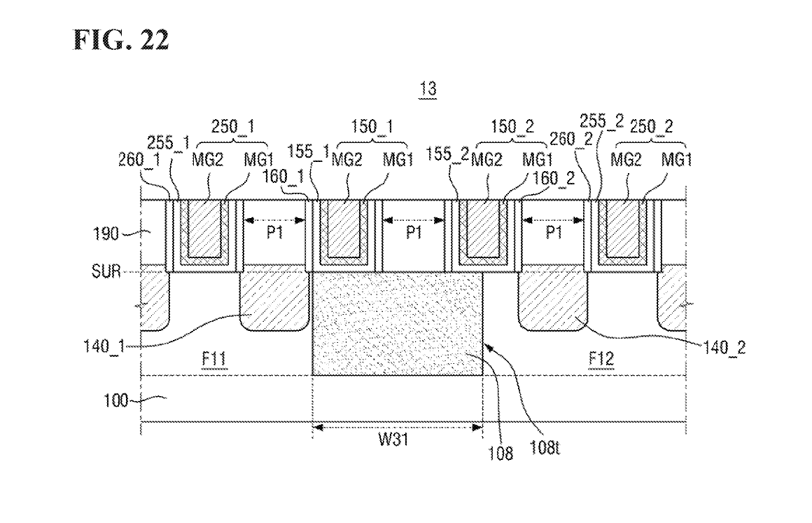

FIG. 22 illustrates a modified example 13 of the semiconductor device 12 of FIGS. 18 through 21. For simplicity, the current modified example 13 will hereinafter be described, focusing mainly on differences with the example embodiment described above with reference to FIGS. 18 through 21.

Referring to FIG. 22, in the modified example 13 of the semiconductor device 12 of FIGS. 18 through 21, at least part of a third gate 150_2 may intersect a second fin pattern F12. That is, a portion of the third gate 150_2 may be located on the second fin pattern F12, and the other portion of the third gate 150_2 may be located on a second field insulating layer 108. Here, a width W31 of the second field insulating layer 108 measured in a first direction X1 may be smaller than the width W3 of the second field insulating layer 108 illustrated in FIG. 21. A second gate 150_1 may be located only on the second field insulating layer 108.

Although not specifically illustrated in the drawing, at least part of the second gate 150_1 may intersect a first fin pattern F11, and the third gate 150_2 may be located only on the second field insulating layer 108. However, the example embodiments of inventive concepts are not limited thereto.

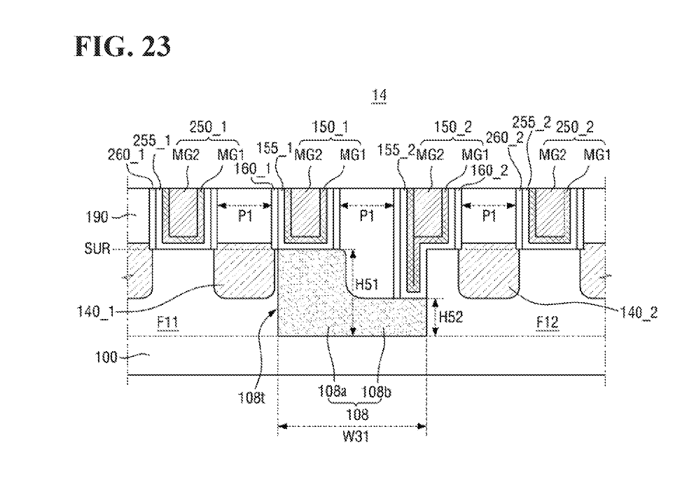

FIG. 23 illustrates another modified example 14 of the semiconductor device 12 of FIGS. 18 through 21. For simplicity, the current modified example 14 will hereinafter be described, focusing mainly on differences with the example embodiment described above with reference to FIGS. 18 through 21.

Referring to FIG. 23, in the modified example 14 of the semiconductor device 12 of FIGS. 18 through 21, a second field insulating layer 108 may include a first portion 108a and a second portion 108b which are located sequentially from a short side of a first fin pattern F11. The first portion 108a and the second portion 108b may have different heights. For example, a height H51 from a lower surface of the first fin pattern F11 to an upper surface of the first portion 108a may be greater than a height H52 from the lower surface of the first fin pattern F11 to an upper surface of the second portion 108b. However, the example embodiments of inventive concepts are not limited thereto, and the opposite is possible.

Here, a second gate 150_1 and a third gate 150_2 may have different shapes.

Specifically, a lower surface of a portion of the third gate 150_2 which is located on the second fin pattern F12 may lie in a different plane from a lower surface of the other portion of the third gate 150_2 which is located on the second portion 108b of the second field insulating layer 108. That is, part of a lower surface of the third gate 150_2 may be at a different height from a lower surface of the second gate 150_1. Accordingly, a third spacer 160_2 located on a side of the third gate 150_2 may have a different shape from another third spacer 160_2 located on the other side of the third gate 150_2.

On the other hand, the lower surface of the second gate 150_1 located on the first portion 108a may lie in the same plane with an upper surface of the first fin pattern F11. That is, the lower surface of the second gate 150_1 and part of the lower surface of the third gate 150_2 may be located in different planes, but the example embodiments of inventive concepts are not limited thereto.

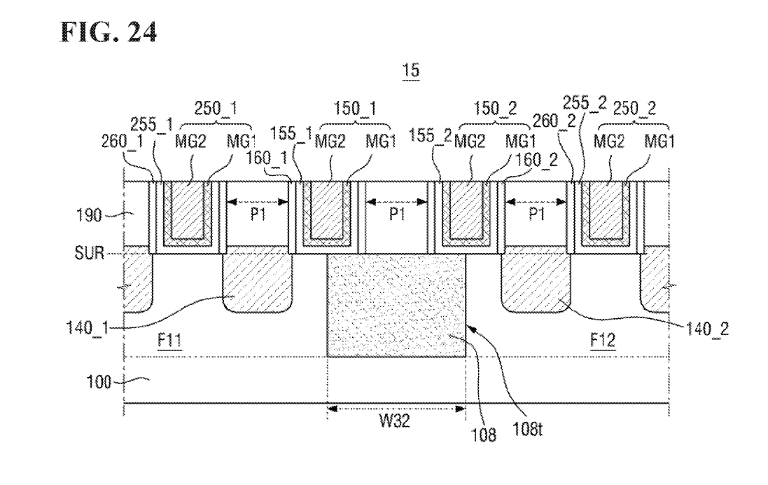

FIG. 24 illustrates another modified example 15 of the semiconductor device 12 of FIGS. 18 through 21. For simplicity, the current modified example 15 will hereinafter be described, focusing mainly on differences with the example embodiment described above with reference to FIGS. 18 through 21.

Referring to FIG. 24, in the modified example 15 of the semiconductor device 12 of FIGS. 18 through 21, at least part of a second gate 150_1 may intersect a first fin pattern F11, and at least part of a third gate 150_2 may intersect a second fin pattern F12.

Specifically, a portion of the second gate 150_1 may be located on the first fin pattern F11, and a portion of the third gate 150_2 may be located on the second fin pattern F12. That is, only part of the second gate 150_1 and only part of the third gate 150_2 may be located on a second field insulating layer 108.

Here, a width W32 of the second field insulating layer 108 measured in a first direction X1 may be smaller than the width W31 of the second field insulating layer 108 illustrated in FIG. 22. However, the example embodiments of inventive concepts are not limited thereto.

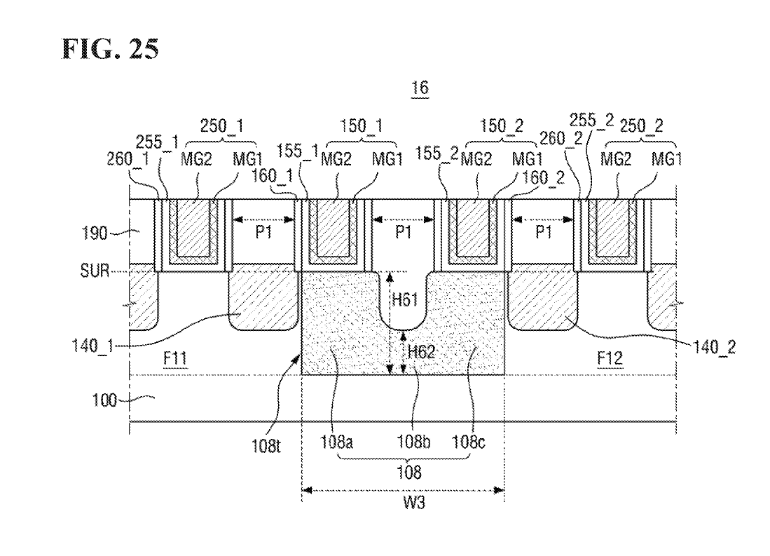

FIG. 25 illustrates another modified example 16 of the semiconductor device 12 of FIGS. 18 through 21. For simplicity, the current modified example 16 will hereinafter be described, focusing mainly on differences with the example embodiment described above with reference to FIGS. 18 through 21.

Referring to FIG. 25, in the modified example 16 of the semiconductor device 12 of FIGS. 18 through 21, a second field insulating layer 108 may include first through third portions 108a through 108c which are located sequentially from a short side of a first fin pattern F11. A height of the first portion 108a may be different from that of the second portion 108b, and a height of the third portion 108c may be equal to that of the first portion 108a. For example, a height H61 from a lower surface of the first fin pattern F11 to an upper surface of the first portion 108a may be greater than a height H62 from the lower surface of the first fin pattern F11 to an upper surface of the second portion 108b. On the other hand, the upper surface of the first portion 108a and an upper surface of the third portion 108c may lie in the same plane. However, the example embodiments of inventive concepts are not limited thereto, and the upper surface of the first portion 108a and the upper surface of the third portion 108c may lie in different planes.

Here, the shape of a second gate 150_1 and the shape of a third gate 150_2 may be symmetrical to each other with respect to the second portion 108b. A lower surface of the second gate 150_1 and a lower surface of the third gate 150_2 may lie in the same plane. Both the second gate 150_1 and the third gate 150_2 may be located on the second field insulating layer 108. In addition, a width W3 of the second field insulating layer 108 measured in a first direction X1 may be, but is not limited to, equal to the width W3 of the second field insulating layer 108 illustrated in FIG. 21.

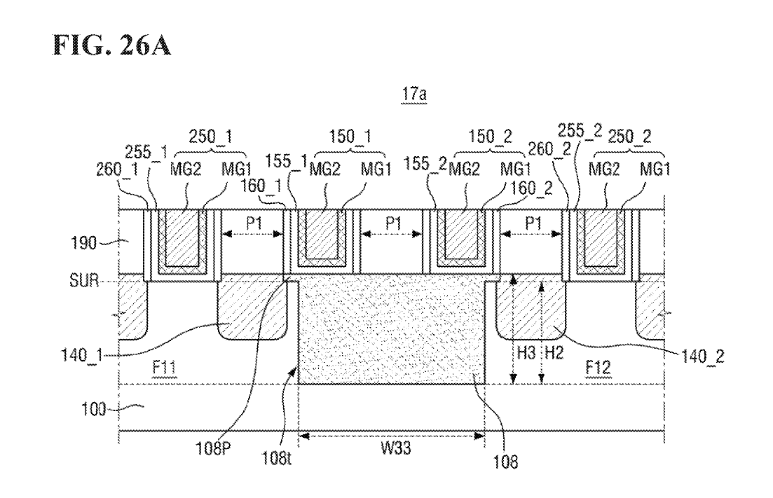

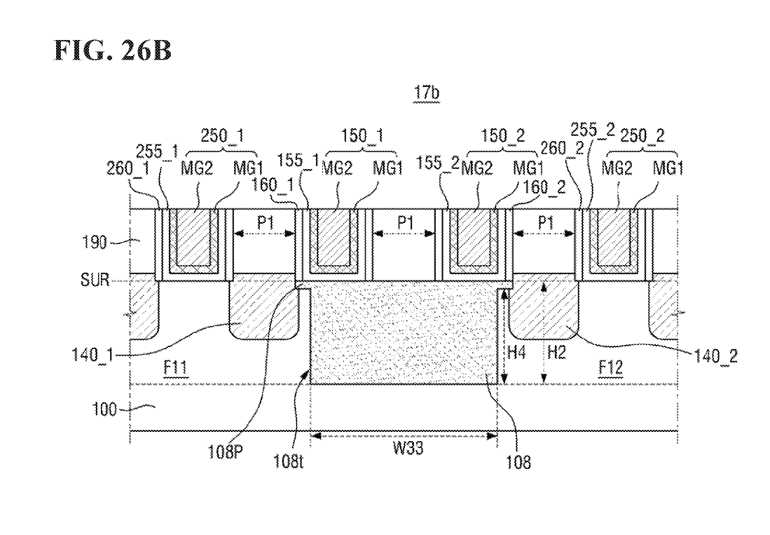

FIG. 26A illustrates another modified example 17a of the semiconductor device 12 of FIGS. 18 through 21. FIG. 26B illustrates another modified example 17b of the semiconductor device 12 of FIGS. 18 through 21. For simplicity, the current modified examples 17a and 17b will hereinafter be described, focusing mainly on differences with the example embodiment described above with reference to FIGS. 18 through 21.

Referring to FIGS. 26A and 26B, in the modified examples 17a and 17b of the semiconductor device 12 of FIGS. 18 through 21, a second field insulating layer 108 may include a protrusion 108P which extends along an upper surface SUR of a first fin pattern F11. In addition, the protrusion 108P may extend along an upper surface SUR of a second fin pattern F12. The second insulating layer 108 including the protrusion 108P may be, e.g., T-shaped.

At least part of a second gate 150_1 may be formed on the protrusion 108P. At least part of the second gate 150_1 may intersect the protrusion 108P. At least part of a third gate 150_2 may also be formed on the protrusion 108P.

In addition, second spacers 160_1 formed on both sidewalls of the second gate 150_1 may be formed on the second field insulating layer 108 including the protrusion 108P. Third spacers 160_2 formed on both sidewalls of the third gate 150_2 may be formed on the second field insulating layer 108 including the protrusion 108P.

Here, a lower surface of the second gate 150_1 and a lower surface of the third gate 150_2 may be, but is not limited to, higher than the upper surface SUR of the first fin pattern F11.

In addition, referring to FIG. 26B, an upper surface of a portion of a first fin pattern F11 which is overlapped by a second gate 150_1 may be lower than an upper surface of a portion of the first fin pattern F11 which is overlapped by a first gate 250_1.

Specifically, a height H4 of the portion of the first fin pattern F11 which is overlapped by the second gate 150_1 may be lower than a height H2 of the portion of the first fin pattern F11 which is overlapped by the first gate 250_1.

In other words, the upper surface of the portion of the first fin pattern F11 which is overlapped by the second gate 150_1 may be more recessed than that of the other portion of the first fin pattern F11.

A second field insulating layer 108 may include a protrusion 108P between the second gate 150_1 and the first fin pattern F11. The protrusion 108P may also be formed between a third gate 150_2 and a second fin pattern F12.

Since the upper surface of the portion of the first fin pattern F11 which is overlapped by the second gate 150_1 is recessed, a first source/drain region 140_1 formed between the second gate 150_1 and the first gate 250_1 may have an asymmetrical shape.

In FIG. 26B, an upper surface of the second field insulating layer 108 lies in the same plane with upper surfaces SUR of the first through third fin patterns F11 through F13. However, this is merely for ease of description, and the example embodiments of inventive concepts are not limited thereto.

Although not specifically illustrated in the drawing, the height H4 of the portion of the first fin pattern F11 which is overlapped by the second gate 150_1 may be higher than the height H2 of the portion of the first fin pattern F11 which is overlapped by the first gate 250_1. That is, the portion of the first fin pattern F11 which is overlapped by the second gate 150_1 may protrude further upward than the upper surface SUR of the first fin pattern F11. However, the example embodiments of inventive concepts are not limited thereto.

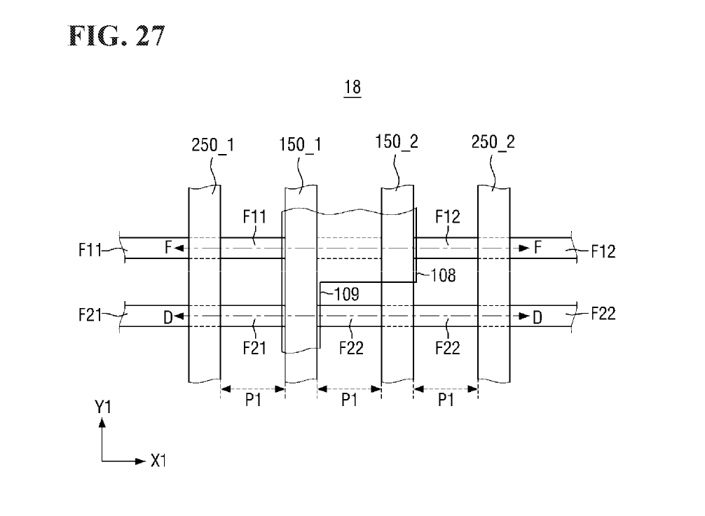

FIG. 27 illustrates a semiconductor device 18 according to another example embodiment of inventive concepts.

Referring to FIG. 27, the semiconductor device 18 according to the current example embodiment may include first through third field insulating layers 103, 108 and 109, first through fourth fin patterns F11, F12, F21 and F22, and first through fourth gates 250_1, 150_1, 150_2 and 250_2.

The first and second fin patterns F11 and F12 may extend along a first direction X1. The first and second fin patterns F11 and F12 may be formed side by side with each other in a lengthwise direction. That is, the first and second fin patterns F11 and F12 may lie on the same line. In addition, the first and second fin patterns F11 and F12 may be separated from each other.

Likewise, the third and fourth fin patterns F21 and F22 may protrude from a substrate 100. The third and fourth fin patterns F21 and F22 may extend along the first direction X1. The third and fourth fin patterns F21 and F22 may be formed side by side with each other in the lengthwise direction. That is, the third and fourth fin patterns F21 and F22 may lie on the same line. In addition, the third and fourth fin patterns F21 and F22 may be separated from each other. Here, the first and second fin patterns F11 and F12 may be separated from the third and fourth fin patterns F21 and F22.

The first field insulating layer 103 may extend along the first direction X1 and cover long sides of the first through fourth fin patterns F11, F12, F21 and F22. The second field insulating layer 108 may be formed between the first fin pattern F11 and the second fin pattern F12. The third field insulating layer 109 may be formed between the third fin pattern F21 and the fourth fin pattern F22.

The first through fourth gates 250_1, 150_1, 150_2 and 250_2 may extend in a second direction Y1 intersecting corresponding fin patterns. Here, the second gate 150_1 may be located on the second field insulating layer 108 and the third field insulating layer 109, and the third gate 150_2 may be located on the second field insulating layer 108 and the fourth fin pattern F22.

Here, a cross-sectional view taken along the line F-F of FIG. 27 is identical to the cross-sectional views of FIGS. 21 through 26B described above, and thus a detailed description thereof is omitted. In addition, a cross-sectional view taken along the line D-D of FIG. 27 is identical to the cross-sectional views of FIGS. 11 through 14B described above, and thus a detailed description thereof is omitted.

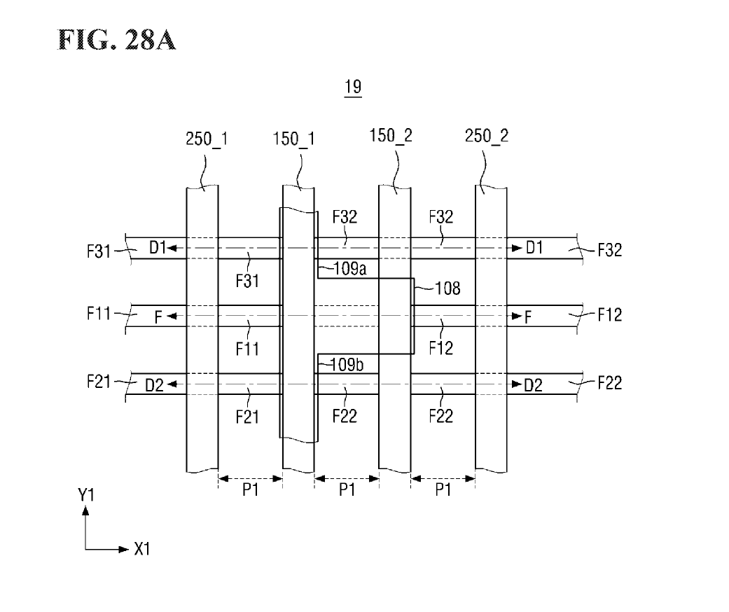

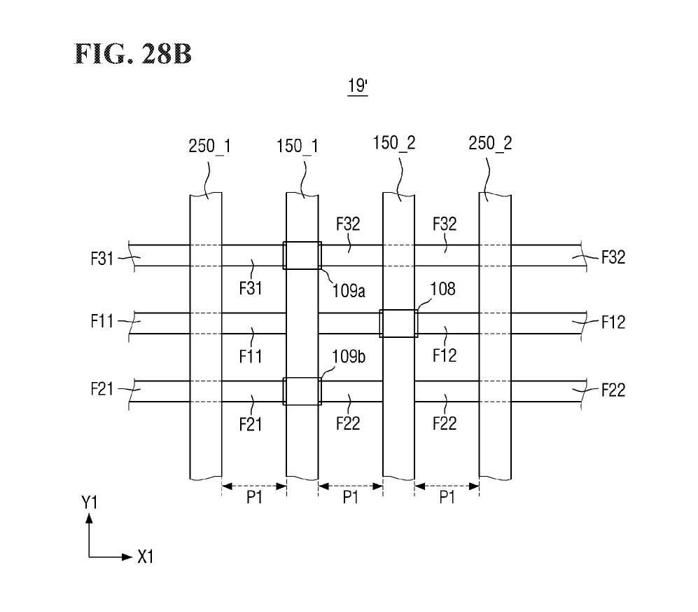

FIGS. 28A and 28B illustrate semiconductor devices 19 and 19′ according to another example embodiment of inventive concepts. For simplicity, a redundant description of elements identical to those of the previous example embodiments will be omitted, and the current example embodiment will hereinafter be described, focusing mainly on differences with the pervious example embodiments.

Referring to FIGS. 28A and 28B, the semiconductor devices 19 and 19′, according to some example embodiments further include a fifth fin pattern F31, a sixth fin pattern F32, and a fourth field insulating layer 109a located between the fifth fin pattern F31 and the sixth fin pattern F32.

Referring to FIG. 28A, part of a second field insulating layer 108, a third field insulating layer 109b, and the fourth field insulating layer 109a may be located on the same straight line and under a second gate 150_1. A third gate 150_2 may be located on the sixth fin pattern F32, a fourth fin pattern F22 and the second field insulating layer 108.

The fourth field insulating layer 109a, the third field insulating layer 109b and the second field insulating layer 108 of FIG. 28A may extend longer in a second direction Y1 than the fourth field insulating layer 109a, the third field insulating layer 109b and the second field insulating layer 108 of FIG. 28B. In other words, in FIG. 28B, the size of the fourth field insulating layer 109a (and/or the second and the third field insulating layers 108 and 109b, respectively) may be reduced as compared to FIG. 28A.

Here, a cross-sectional view taken along the line F-F of FIG. 28A is identical to the cross-sectional views of FIGS. 21 through 26B described above, and thus a detailed description thereof is omitted. Cross-sectional views taken along the lines D1-D1 and D2-D2 of FIG. 27 are identical to the cross-sectional views of FIGS. 11 through 14B described above, and thus a detailed description thereof is omitted.

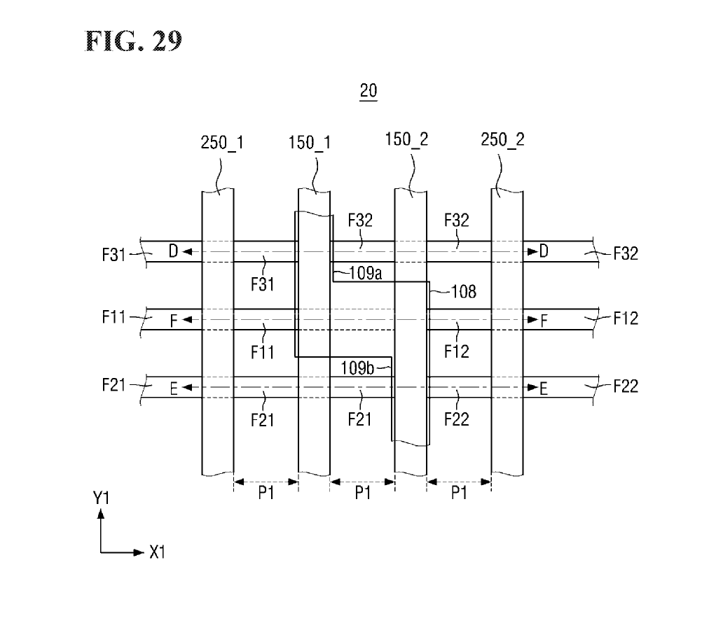

FIG. 29 illustrates a semiconductor device 20 according to another example embodiment of inventive concepts. For simplicity, a redundant description of elements identical to those of the previous example embodiments will be omitted, and the current example embodiment will hereinafter be described, focusing mainly on differences with the pervious example embodiments.

Referring to FIG. 29, the semiconductor device 20 according to the current example embodiment is substantially similar to the semiconductor device 19 described above with reference to FIG. 28A. However, a second gate 150_1 may be disposed on a fourth field insulating layer 109a, a second field insulating layer 108 and a third fin pattern F21, and a third gate 150_2 may be disposed on a sixth fin pattern F32, the second field insulating layer 108 and a third field insulating layer 109b.

Here, a cross-sectional view taken along the line F-F of FIG. 29 is identical to the cross-sectional views of FIGS. 21 through 26B described above, and thus a detailed description thereof is omitted. Cross-sectional views taken along the lines D-D of FIG. 29 are identical to the cross-sectional views of FIGS. 11 through 14B described above, and thus a detailed description thereof is omitted. A cross-sectional view taken along the line E-E of FIG. 29 is identical to the cross-sectional views of FIGS. 11 through 14B described above, and thus a detailed description thereof is omitted.

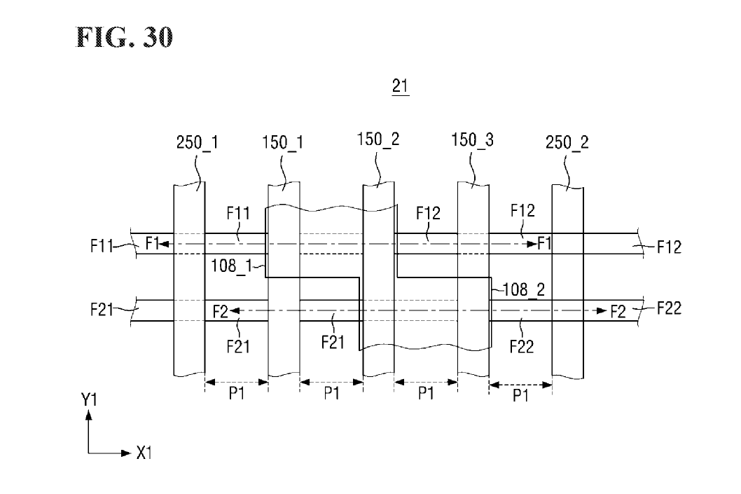

FIG. 30 illustrates a semiconductor device 21 according to another example embodiment of inventive concepts. For simplicity, a redundant description of elements identical to those of the previous example embodiments will be omitted, and the current example embodiment will hereinafter be described, focusing mainly on differences with the pervious example embodiments.

Referring to FIG. 30, the semiconductor device 21 according to the current example embodiment may include first through third field insulating layers 103, 108_1 and 108_2, first through fourth fin patterns F11, F12, F21 and F22, and first through fifth gates 250_1, 150_1, 150_2, 150_3 and 250_2.

Here, cross-sectional views taken along the lines F1-F1 and F2-F2 of FIG. 30 are identical to the cross-sectional views of FIGS. 21 through 26B described above, and thus a detailed description thereof is omitted.

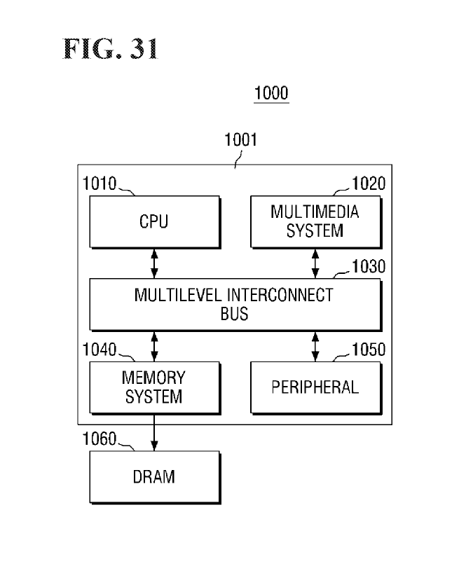

FIG. 31 is a block diagram of a system-on-chip (SoC) system 1000 including semiconductor devices according to example embodiments of inventive concepts.

Referring to FIG. 31, the SoC system 1000 includes an application processor 1001 and a dynamic random access memory (DRAM) 1060.

The application processor 1001 may include a central processing unit (CPU) 1010, a multimedia system 1020, a bus 1030, a memory system 1040, and a peripheral circuit 1050.

The CPU 1010 may perform operations needed to drive the SoC system 1000. In some example embodiments of inventive concepts, the CPU 1010 may be configured as a multi-core environment including a plurality of cores.

The multimedia system 1020 may be used to perform various multimedia functions in the SoC system 1000. The multimedia system 1020 may include a 3D engine module, a video codec, a display system, a camera system, and a post-processor.

The bus 1030 may be used for data communication among the CPU 1010, the multimedia system 1020, the memory system 1040 and the peripheral circuit 1050. In some example embodiments of inventive concepts, the bus 1030 may have a multilayer structure. Specifically, the bus 1030 may be, but is not limited to, a multilayer advanced high-performance bus (AHB) or a multilayer advanced extensible interface (AXI).

The memory system 1040 may provide an environment needed for the application processor 1001 to be connected to an external memory (e.g., the DRAM 1060) and operate at high speed. In some example embodiments, the memory system 1040 may include a controller (e.g., a DRAM controller) for controlling the external memory (e.g., the DRAM 1060).

The peripheral circuit 1050 may provide an environment needed for the SoC system 1000 to smoothly connect to an external device (e.g., mainboard). Accordingly, the peripheral circuit 1050 may include various interfaces that enable the external device connected to the SoC system 1000 to be compatible with the SoC system 1000.

The DRAM 1060 may function as a working memory needed for the operation of the application processor 1001. In some example embodiments, the DRAM 1060 may be placed outside the application processor 1001 as illustrated in the drawing. Specifically, the DRAM 1060 may be packaged with the application processor 1001 in the form of package on package (PoP).

At least one of the elements of the SoC system 1000 may employ any one of the semiconductor devices according to the above-described example embodiments of inventive concepts.

In addition, the SoC system 1000 described above may be applied to nearly all types of electronic products capable of transmitting and/or receiving information in a wireless environment, such as a personal data assistant (PDA), a portable computer, a web tablet, a wireless phone, a mobile phone, a digital music player, a memory card, etc.

While the example embodiments of inventive concepts have been particularly shown and described with reference to example embodiments thereof, it will be understood by those of ordinary skill in the art that various changes in form and details may be made therein without departing from the spirit and scope of the example embodiments of inventive concepts as defined by the following claims. It is therefore desired that the example embodiments be considered in all respects as illustrative and not restrictive, reference being made to the appended claims rather than the foregoing description to indicate the scope of the example embodiments of inventive concepts.

1. A semiconductor device comprising:
a first fin pattern and a second fin pattern which have respective short sides facing each other and are separated from each other;
a first field insulating layer around the first fin pattern and the second fin pattern;
a second field insulating layer and a third field insulating layer between the first fin pattern and the second fin pattern;
a first gate on the first fin pattern to intersect the first fin pattern;
a second gate on the second field insulating layer; and
a third gate on the third field insulating layer,
wherein upper surfaces of the second and third field insulating layers protrude further upward than an upper surface of the first field insulating layer, and a distance between the first gate and the second gate is equal to a distance between the second gate and the third gate.

2. The semiconductor device 1, further comprising a third fin pattern between the second field insulating layer and the third field insulating layer, wherein the third fin pattern lies on the same line as the first and second fin patterns.

3. The semiconductor device of claim 2, wherein a width of the second field insulating layer is equal to that of the third field insulating layer in a direction of long sides of the first fin pattern extend.

4. The semiconductor device of claim 2, wherein a height of the second field insulating layer from a lower surface of the first fin pattern is equal to a height of the third field insulating layer from the lower surface of the first fin pattern.

5. The semiconductor device of claim 1, wherein the second field insulating layer and the third field insulating layer are as a single layer, and no fin pattern is between the second field insulating layer and the third field insulating layer.

6.-7. (canceled)

8. The semiconductor device of claim 5, wherein the second field insulating layer and the third field insulating layer have different heights.

9. The semiconductor device of claim 1, further comprising an elevated source/drain region in the first fin pattern between the first gate and the second gate, wherein the elevated source/drain region has an asymmetrical shape.

10. (canceled)

11. The semiconductor device of claim 1, wherein the upper surface of the second field insulating layer or the third field insulating layer is at a height equal to or higher than an upper surface of the first fin pattern.

12. The semiconductor device of claim 1, wherein the second field insulating layer further comprises a protrusion extends along the upper surface of the first fin pattern.

13.-17. (canceled)

18. The semiconductor device of claim 1, further comprising a third fin pattern and a fourth fin pattern which have respective short sides facing each other and are separated from each other, wherein the first field insulating layer is around the third fin pattern and the fourth fin pattern, the second field insulating layer is between the third fin pattern and the fourth fin pattern, the second gate is on the second field insulating layer between the third fin pattern and the fourth fin pattern, and the third gate is on the fourth fin pattern.

19. (canceled)

20. (canceled)

21. The semiconductor device of claim 18, further comprising a fifth fin pattern and a sixth fin pattern which have respective short sides facing each other and are separated from each other, wherein the second field insulating layer or the third field insulating layer is between the fifth fin pattern and the sixth fin pattern.

22. A semiconductor device comprising:
first through third fin patterns which have respective short sides facing each other and are separated from each other;
a first field insulating layer around the first through third fin patterns;
a second field insulating layer between the first fin pattern and the second fin pattern;
a third field insulating layer between the second fin pattern and the third fin pattern;
a first gate on the first fin pattern to intersect the first fin pattern;
a second gate on the second field insulating layer; and
a third gate on the third field insulating layer,
wherein upper surfaces of the second and third field insulating layers protrude further upward than an upper surface of the first field insulating layer.

23. The semiconductor device of claim 22, wherein a distance between the first gate and the second gate is equal to a distance between the second gate and the third gate.

24. (canceled)

25. (canceled)

26. The semiconductor device of claim 22, further comprising a fourth fin pattern and a fifth fin pattern which have respective short sides facing each other and are separated from each other, wherein the first field insulating layer is around the fourth fin pattern and the fifth fin pattern, the second field insulating layer is between the fourth fin pattern and the fifth fin pattern, the second gate is on the second field insulating layer between the fourth fin pattern and the fifth fin pattern, and the third gate is on the fifth fin pattern.

27. The semiconductor device of claim 26, wherein a region between the first fin pattern and the second fin pattern lies on the same line as a region between the forth fin pattern and the fifth fin pattern.

28.-31. (canceled)

32. The semiconductor device of claim 26, further comprising a sixth fin pattern and a seventh fin pattern which have respective short sides facing each other and are separated from each other, wherein the second field insulating layer or the third field insulating layer is between the sixth fin pattern and the seventh fin pattern.

33.-35. (canceled)

36. A semiconductor device comprising:
a first fin pattern and a second fin pattern which have respective short sides facing each other and are separated from each other;
a first field insulating layer around the first fin pattern and the second fin pattern;
a second field insulating layer between the first fin pattern and the second fin pattern;
a first gate on the first fin pattern to intersect the first fin pattern;
a second gate on the second field insulating layer on one side; and
a third gate on the second field insulating layer on the other side; and
a fourth gate on the second fin pattern to intersect the second fin pattern,
wherein an upper surface of the second field insulating layer protrudes further upward than an upper surface of the first field insulating layer, and the first through fourth gates are sequentially arranged at regular intervals.

37. (canceled)

38. The semiconductor device of claim 36, wherein the upper surface of the second field insulating layer is at a height equal to or higher than upper surfaces of the first and second fin patterns.

39. The semiconductor device of claim 36, wherein the second field insulating layer comprises a first portion and a second portion sequentially from a short side of the first fin pattern, wherein a height of the first portion is different from that of the second portion.

40. (canceled)

41. (canceled)

42. The semiconductor device of claim 36, wherein the second field insulating layer comprises first through third portions sequentially from a short side of the first fin pattern, wherein a height of the first portion is different from that of the second portion, and a height of the third portion is equal to that of the first portion.

43.-54. (canceled)
